(19) United States
(12) Patent Application Publication
(10) Pub. No.: US 2024/0306389 A1
(43) Pub. Date: Sep. 12, 2024

(54) MEMORY DEVICE AND METHOD OF MANUFACTURING THE SAME

(71) Applicant: SAMSUNG ELECTRONICS CO., LTD., SUWON-SI (KR)

(72) Inventors: Kohji Kanamori, Suwon-si (KR); Jeehoon Han, Suwon-si (KR)

(21) Appl. No.: 18/591,486

(22) Filed: Feb. 29, 2024

(30) Foreign Application Priority Data
Mar. 10, 2023 (KR) 10-2023-0031880

(51) Int. Cl. H10B 43/27; G11C 16/08; H10B 41/10; H10B 41/27; H10B 41/40; H10B 43/10; H10B 43/40

(52) U.S. Cl. CPC H10B 43/27; H10B 41/10; H10B 41/27; H10B 41/40; H10B 43/10; H10B 43/40; G11C 16/08

(57) ABSTRACT

A memory device includes a first bit line pad and a second bit line pad on a substrate and separated from each other in a first horizontal direction, a plurality of horizontal channel areas extending parallel in the first horizontal direction between the first bit line pad and the second bit line pad, and alternately connected to the first bit line pad and the second bit line pad at first end portions of the plurality of horizontal channel areas, a plurality of common source plugs connected to the second end portions of the plurality of horizontal channel areas opposite to the first end portions, and a plurality of gate plugs extending in a vertical direction and disposed between the plurality of horizontal channel areas, and respectively having end portions in a second horizontal direction perpendicular to the first horizontal direction in contact with the plurality of horizontal channel areas.

### CROSS-REFERENCE TO RELATED APPLICATION

This application is based on and claims priority under 35 U.S.C. § 119 to Korean Patent Application No. 10-2023-0031880, filed on Mar. 10, 2023, in the Korean Intellectual Property Office, the disclosure of which is incorporated by reference herein in its entirety.

### TECHNICAL FIELD

The inventive concept relates to a memory device, and more particularly, to a nonvolatile memory device including a horizontal channel area.

### DESCRIPTION OF RELATED ART

To improve the performance of electronic devices and semiconductor devices thereof, the electronic devices may be scaled down and an integration of the semiconductor devices may be increased. One method of increasing the degree of integration of the semiconductor devices that has been proposed is a three-dimensional nonvolatile memory. The three-dimensional nonvolatile memory devices may have a structure with reliability needed for memory cells even when a number of vertically overlapping memory cells stacked on a substrate is large.

### SUMMARY

The inventive concept provides a memory device with increased electrical reliability and an increased degree of integration of a memory cell array of the memory device.

The inventive concept provides a method of manufacturing a memory device with increased electrical reliability and integration of a memory cell array.

According to an aspect of the inventive concept, a memory device includes a first bit line pad and a second bit line pad on a substrate and separated from each other in a first horizontal direction, a plurality of horizontal channel areas extending parallel in the first horizontal direction between the first bit line pad and the second bit line pad and alternately connected to the first bit line pad and the second bit line pad at first end portions of the plurality of horizontal channel areas, a plurality of common source plugs connected to second end portions of the plurality of horizontal channel areas opposite to the first end portions, and a plurality of gate plugs extending in a vertical direction and disposed between the plurality of horizontal channel areas and respectively having end portions in a second horizontal direction perpendicular to the first horizontal direction in contact with the plurality of horizontal channel areas.

According to another aspect of the inventive concept, a memory device includes a cell array structure including a plurality of memory cells arranged on a substrate in a first horizontal direction and a second horizontal direction, which are parallel to a surface of the substrate and are orthogonal to each other, and in a vertical direction perpendicular to the surface, wherein the cell array structure includes a plurality of first horizontal channel areas including a first group extending parallel to each other in the first horizontal direction and a second group overlapping each other at a plurality of vertical levels and separated from each other in the vertical direction on the substrate, a plurality of second horizontal channel areas separated from the plurality of first horizontal channel areas in the second horizontal direction and including a third group extending parallel to each other in the first horizontal direction, and a fourth group overlapping each other at the plurality of vertical levels and separated from each other in the vertical direction on the substrate, a plurality of gate plugs extending in the vertical direction between the first group of the plurality of first horizontal channel areas and the third group of the plurality of second horizontal channel areas, each having first end portions in contact with the plurality of first horizontal channel areas, and each having second end portions in contact with the plurality of second horizontal channel areas, and a plurality of bit line pad layers each including a first bit line pad and a second bit line pad separated from each other in the first horizontal direction with the plurality of first horizontal channel areas and the plurality of second horizontal channel areas therebetween and the plurality of bit line pad layers overlap each other at the plurality of vertical levels and separated from each other in the vertical direction, wherein a first bit line pad layer of the plurality of bit line pad layers is disposed at a first vertical level of the plurality of vertical levels, the first bit line pad of the first bit line pad layer in contact with first end portions of the first group of the plurality of first horizontal channel areas at the first vertical level, and the second bit line pad of the first bit line pad layer in contact with first end portions of the third group of the plurality of second horizontal channel areas at the first vertical level.

According to another aspect of the inventive concept, a memory device includes a plurality of first bit line pad stacks and a plurality of second bit line pad stacks alternately separated from each other in a first horizontal direction, and a plurality of memory cell blocks respectively arranged between the plurality of first bit line pad stacks and the plurality of second bit line pad stacks in the first horizontal direction, wherein each of the plurality of memory cell blocks includes a plurality of first horizontal channel areas extending in the first horizontal direction and repeatedly arranged in a second horizontal direction perpendicular to the first horizontal direction and in a vertical direction on a substrate, a plurality of second horizontal channel areas separated from the plurality of first horizontal channel areas in the second horizontal direction, extending in the first horizontal direction, and repeatedly arranged in the second horizontal direction and the vertical direction on the substrate, and a plurality of gate plugs extending in the vertical direction, each having first end portions in contact with some of the plurality of first horizontal channel areas and second end portions opposite to the first end portions in the second horizontal direction in contact with some of the plurality of second horizontal channel areas, wherein the plurality of first bit line pad stacks include a plurality of first bit line pads, wherein the plurality of first bit line pads extend in the second horizontal direction and are in contact with the plurality of first horizontal channel areas, and overlap each other at positions separated from each other in the vertical direction, the plurality of second bit line pad stacks include a plurality of second bit line pads, wherein the plurality of second bit line pads extend in the second horizontal direction and are in contact with the plurality of second horizontal channel areas, and overlap each other at positions separated from each other in the vertical direction, and the plurality of first horizontal channel areas and the plurality of second horizontal channel areas are alternately arranged along the second horizontal direction.

### BRIEF DESCRIPTION OF THE DRAWINGS

Embodiments will be more clearly understood from the following detailed description taken in conjunction with the accompanying drawings in which:

FIG. 1 is a block diagram of a memory device according to an embodiment;

FIG. 2A, FIG. 2B, FIG. 2C, FIG. 2D, FIG. 2E, and FIG. 2F are equivalent circuit diagrams of a memory cell array of a memory device, according to embodiments;

FIG. 3A is a perspective view illustrating a representative configuration of a memory device according to an embodiment;

FIG. 3B is a plan view illustrating a cell array structure of a memory device according to an embodiment;

FIG. 3C is a plan view illustrating a main configuration of a peripheral circuit structure of a memory device according to an embodiment;

FIG. 4 is an enlarged view of an area indicated by “EX1” in FIG. 3B;

FIG. 5 is an enlarged view of an area indicated by “EX2” in FIG. 4;

FIG. 6 is a perspective view illustrating a main configuration of a memory device according to an embodiment;

FIG. 7A is a cross-sectional view taken along line A-A′ of FIG. 4;

FIG. 7B is a cross-sectional view taken along line B-B′ of FIG. 4;

FIG. 8 is an enlarged view of an area indicated by “EX3” in FIG. 4;

FIG. 9A and FIG. 9B are enlarged views of an area indicated by “EX4” in FIG. 4;

FIG. 10 is a cross-sectional view taken along line C-C′ of FIG. 9A;

FIG. 11A and FIG. 11B are enlarged view of an area indicated by “EX5” in FIG. 4;

FIG. 12 is an enlarged view of an area indicated by “EX6” in FIG. 11A;

FIG. 13 is a plan view illustrating a main configuration of a peripheral circuit structure of a memory device according to another embodiment;

FIG. 14A is a plan view illustrating a cell array structure of a memory device according to another embodiment and is an enlarged view of a corresponding part in FIG. 4;

FIG. 14B is a cross-sectional view taken along line D-D′ of FIG. 14A;

FIG. 15A, FIG. 15B, and FIG. 15C are plan views illustrating an operating method of a memory device, according to embodiments, and are enlarged views of corresponding to a portion of FIG. 9A; and

FIG. 16A, FIG. 17A, FIG. 18A, and FIG. 19A are cross-sectional views illustrating process sequence a method of manufacturing a memory device, according to an embodiment, and FIG. 16B, FIG. 17B, FIG. 18B, and FIG. 19B are plan views respectively illustrating configurations of FIG. 16A, FIG. 17A, FIG. 18A, and FIG. 19A at a second vertical level.

### DETAILED DESCRIPTION

Hereinafter, embodiments will be described in detail with reference to the accompanying drawings. The same reference numerals may be used for the same components in the drawings, and redundant descriptions thereof may be omitted.

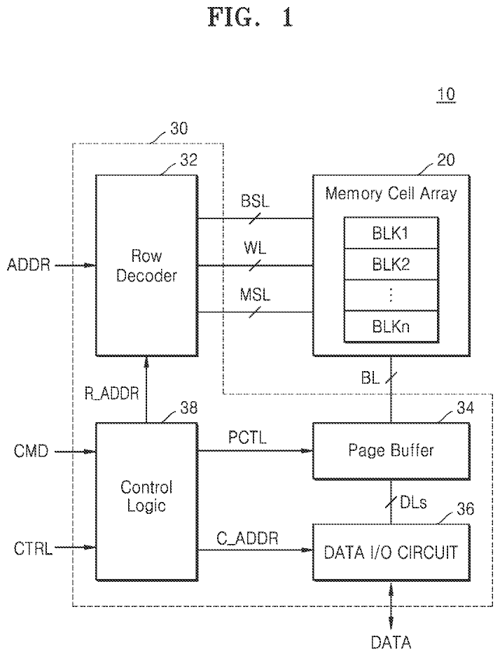

FIG. 1 is a block diagram of a semiconductor device 10 according to an embodiment.

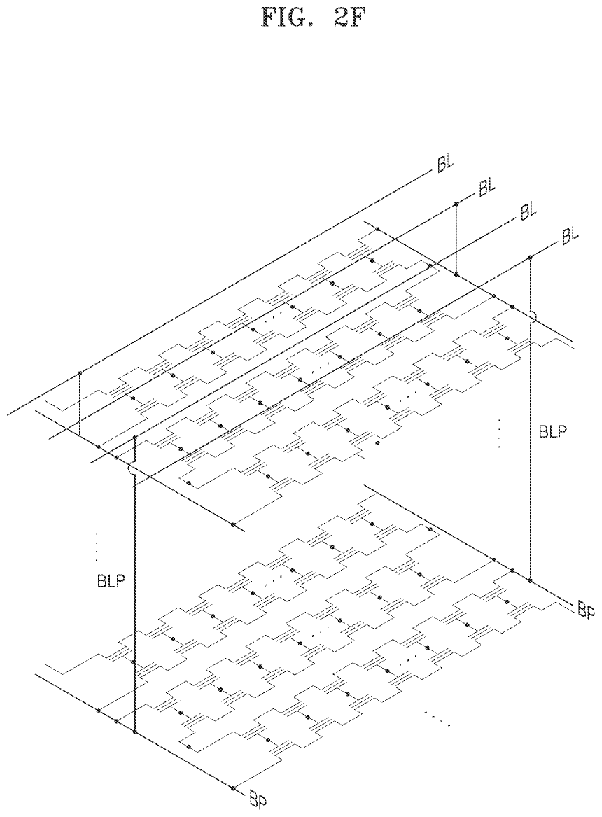

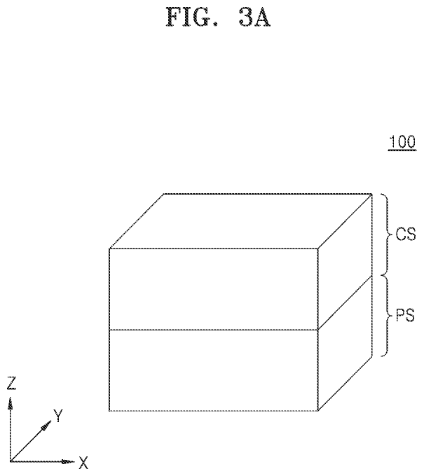

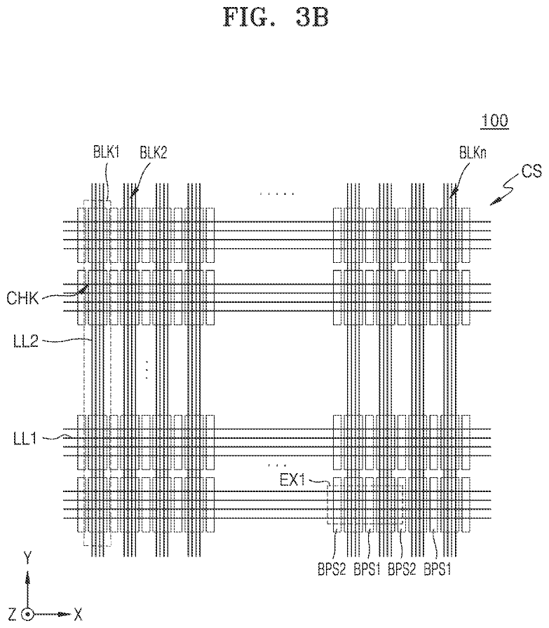

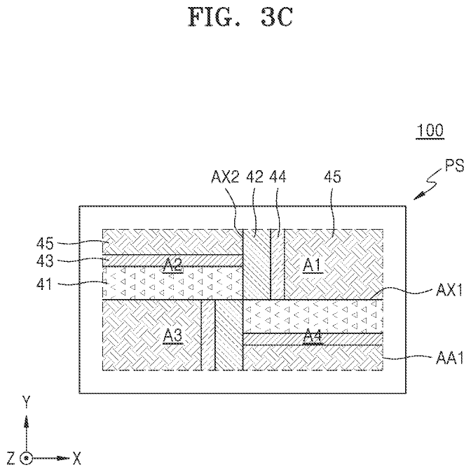

Referring to FIG. 1, the semiconductor device 10 may include a memory cell array 20 and a peripheral circuit 30. The memory cell array 20 may include a plurality of memory cell blocks BLK1, BLK2, . . . , BLKn. Each of the plurality of memory cell blocks BLK1, BLK2, . . . , BLKn may include a plurality of chunks CHK (see for example, FIG. 3B), and each of the plurality of chunks may include a plurality of memory cells. The plurality of memory cell blocks BLK1, BLK2, . . . , BLKn may be connected to the peripheral circuit 30 through bit lines BL, block select lines BSL, word lines WL, and multi-select lines MSL. The multi-select lines MSL may function as string select lines or ground select lines.

According to embodiments, the peripheral circuit 30 may include a row decoder 32, a page buffer 34, a data input/output (I/O) circuit 36, and a control logic 38. Although not illustrated in FIG. 1, the peripheral circuit 30 may further include an input/output interface, a column logic, a voltage generator, a pre-decoder, a temperature sensor, a command decoder, an address decoder, an amplifier circuit, and so on.

According to an embodiment, the memory cell array 20 may be connected to the page buffer 34 through the bit lines BL and may be connected to the row decoder 32 through the block select lines BSL, the word lines WL, and the multi-select lines MSL. Each of a plurality of memory cells included in the plurality of memory cell blocks BLK1, BLK2, . . . , BLKn of the memory cell array 20 may be a flash memory cell. The memory cell array 20 may include a three-dimensional (3D) memory cell array. The 3D memory cell array may include a plurality of NAND strings, and each of the plurality of NAND strings may include a plurality of memory cells connected to a plurality of gate plugs extending in a vertical direction on a substrate.

According to an embodiment, the peripheral circuit 30 may receive an address signal ADDR, a command signal CMD, and a control signal CTRL from the outside of the semiconductor device 10 and may transmit and receive data DATA to and from an external device.

According to an embodiment, the row decoder 32 may select the block select lines BSL, the word lines WL, and the multi-select lines MSL in response to an external address signal ADDR. For example, at least one of the plurality of memory cell blocks BLK1, BLK2, . . . , BLKn may be selected through the block select lines BSL, and the row decoder 32 may select the word lines WL and the multi-select lines MSL of the selected memory cell block. The row decoder 32 may transmit a voltage for a memory operation to the word lines WL of the selected memory cell block.

According to an embodiment, the page buffer 34 may be connected to the memory cell array 20 through the bit lines BL. The page buffer 34 may apply a voltage according to data DATA to be stored in the memory cell array 20 to the bit lines BL by operating as a write driver during a program operation and may detect the data DATA stored in the memory cell array 20 by operating as a sense amplifier during a read operation. The page buffer 34 may operate in response to the control signal PCTL provided from the control logic 38.

The data input/output circuit 36 may be connected to the page buffer 34 through data lines DLs. The data input/output circuit 36 may receive the data from a memory controller (not illustrated) during a program operation and transmit program data to the page buffer 34 in response to a column address signal C_ADDR provided from the control logic 38. During the read operation, the data input/output circuit 36 may provide read data stored in the page buffer 34 to the memory controller in response to the column address signal C_ADDR provided from the control logic 38.

The data input/output circuit 36 may transmit an input address signal or an input command signal to the control logic 38 or the row decoder 32. The peripheral circuit 30 may further include an electrostatic discharge (ESD) circuit and a pull-up/pull-down driver.

The control logic 38 may receive the command signal CMD and the control signal CTRL from the memory controller. The control logic 38 may provide a row address signal R_ADDR to the row decoder 32 and the column address signal C_ADDR to the data input/output circuit 36. The control logic 38 may generate various internal control signals used in the semiconductor device 10 in response to the control signal CTRL. For example, the control logic 38 may adjust levels of voltages provided to the word lines WL and the bit lines BL during a memory operation, such as a program operation or an erase operation.

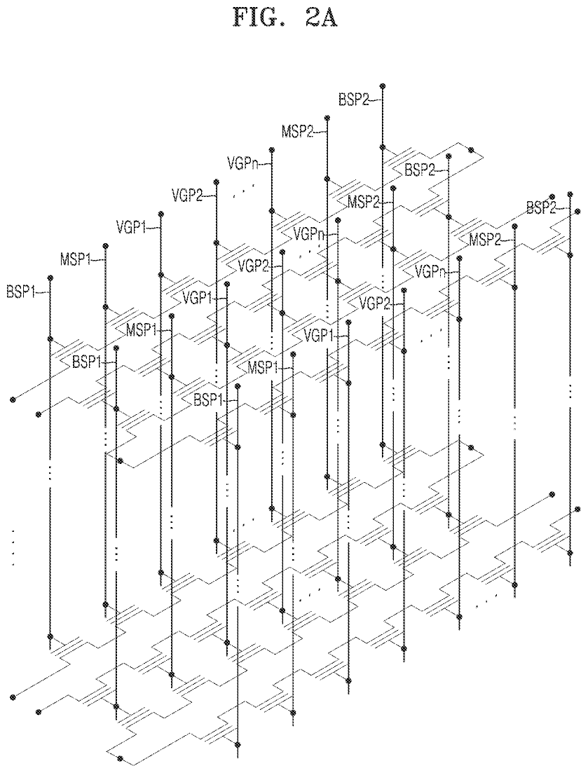

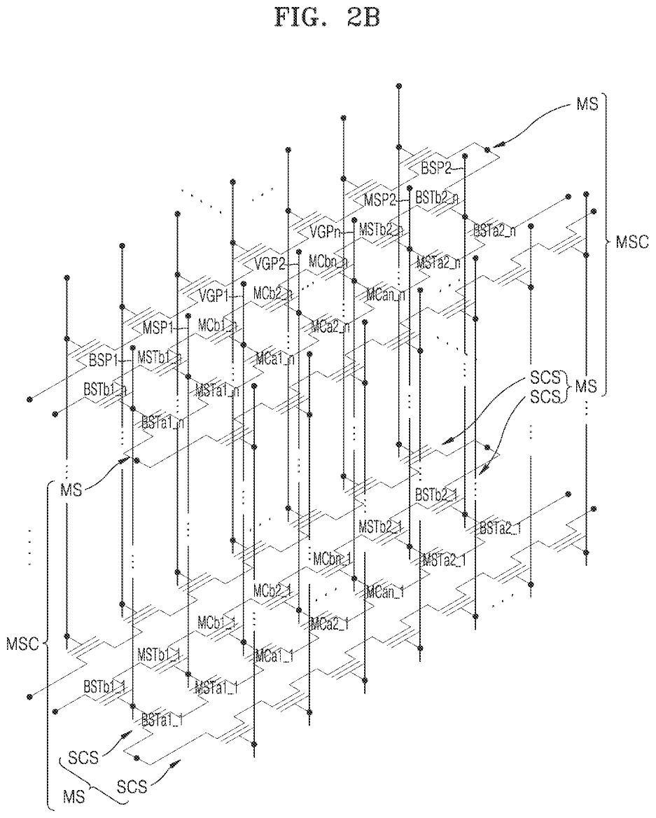

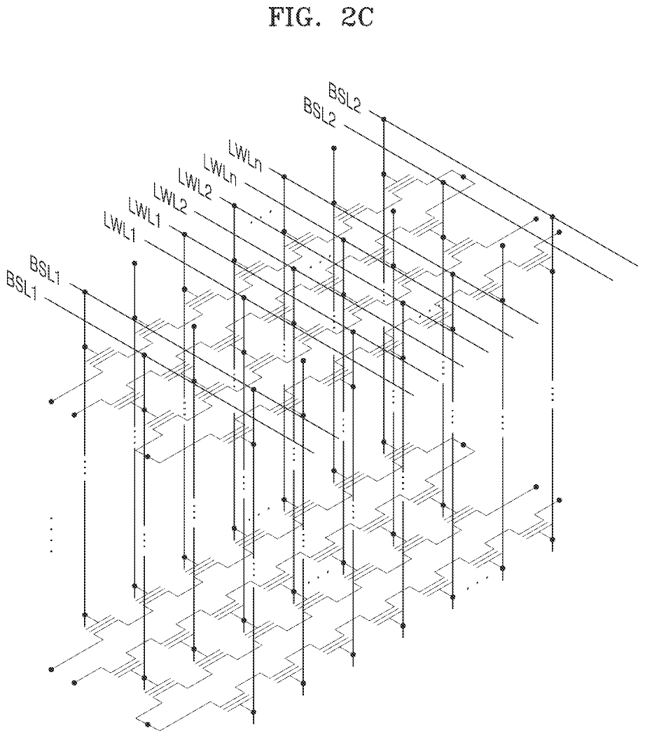

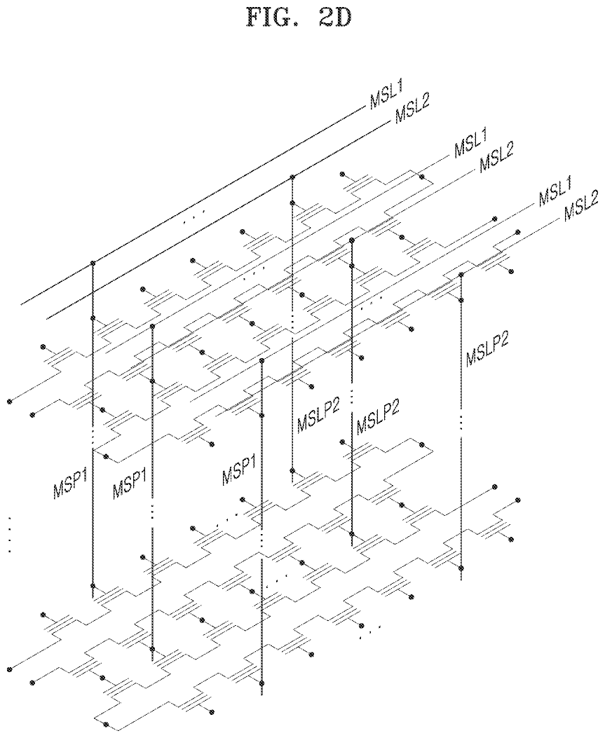

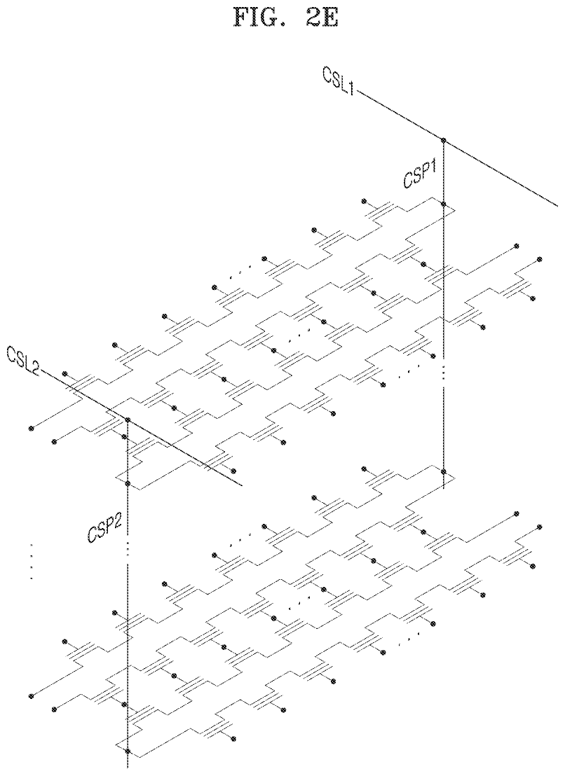

FIG. 2A, FIG. 2B, FIG. 2C, FIG. 2D, FIG. 2E, and FIG. 2F are equivalent circuit diagrams of a memory cell array 20 (see for example, FIG. 1) of the semiconductor device 10, according to embodiments. Specifically, FIGS. 2A to 2F respectively illustrate examples of some components for the sake of convenience of description of an equivalent circuit diagram of the memory cell array 20 according to an embodiment, and the equivalent circuit diagram of the memory cell array 20 according to an embodiment may be a combination of the configurations of FIG. 2A, FIG. 2B, FIG. 2C, FIG. 2D, FIG. 2E, and FIG. 2F.

Referring to FIG. 2A, the memory cell array 20 may include a plurality of gate plugs VGP1, VGP2, . . . , VGPn, a plurality of first and second block select plugs BSP1 and BSP2, and a plurality of multi-select plugs MSP1 and MSP2.

Referring to FIG. 2A and FIG. 2B, the memory cell array 20 according to an embodiment may have a structure in which double cell structures may be three-dimensionally arranged in extension direction of the conductive plug. The double cell structures may each have two transistors to which a gate voltage is applied through one conductive plug.

According to embodiments, a plurality of first gate plugs VGP1 selected from among the plurality of gate plugs VGP1, VGP2, . . . , VGPn may respectively apply gate voltages to a plurality of first memory cell columns MCa1_1, . . . , MCa1_n and a plurality of second memory cell columns MCb1_1, . . . , MCb1_n. For example, the plurality of first memory cell columns MCa1_1, . . . , MCa1_n and the plurality of second memory cell columns MCb1_1, . . . , MCb1_n may be three-dimensionally arranged in extension directions of the plurality of first gate plugs VGP1. Similar to the plurality of first gate plugs VGP1, the plurality of second gate plugs VGP2 selected from among the plurality of gate plugs VGP1, VGP2, . . . , VGPn may respectively apply gate voltages to a plurality of third memory cell columns MCa2_1, . . . , MCa2_n and a plurality of fourth memory cell columns MCb2_1, . . . , MCb2_n, and the plurality of n-th gate plugs VGPn selected from among the plurality of gate plugs VGP1, VGP2, . . . , VGPn may respectively apply gate voltages to a plurality of (2n−1)-th memory cell columns MCan_1, . . . , MCan_n and a plurality of 2n-th memory cell columns MCbn_1, . . . , MCbn_n.

According to embodiments, the plurality of first block select plugs BSP1 may respectively apply gate voltages to a plurality of first block select transistor columns BSTa1_1, . . . , BSTa1_n and a plurality of second block select transistor columns BSTb1_1, . . . , BSTb1_n, and the plurality of second block select plugs BSP2 may respectively apply gate voltages to a plurality of third block select transistor columns BSTa2_1, . . . , BSTa2_n and a plurality of fourth block select transistor columns BSTb2_1, . . . , BSTb2_n.

According to embodiments, the plurality of first multi-select plugs MSP1 may respectively apply gate voltages to a plurality of first multi-select transistor columns MSTa1_1, . . . , MSTa1_n and a plurality of second multi-select transistor columns MSTb1_1, . . . , MSTb1_n, and the plurality of second multi-select plugs MSP2 may respectively apply gate voltages to a plurality of third multi-select transistor columns MSTa2_1, . . . , MSTa2_n and a plurality of fourth multi-select transistor columns MSTb2_1, . . . , MSTb2_n.

According to an embodiment, the memory cell array 20 may include a plurality of memory cell string columns MSC. Each of the plurality of memory cell string columns MSC may include a plurality of memory cell strings MS sharing a common source plug (see for example, FIG. 2E).

According to embodiments, each of the plurality of memory cell strings MS may include two sub-cell strings SCS connected to different gate plugs. According to embodiments, the two sub-cell strings SCS, which may be adjacent to each other and connected to different source areas, may share a gate terminal through a plurality of conductive plugs (for example, BSP1, MSP1, VGP1, VGP2, . . . , VGPn, MSP2, BSP2).

Referring to FIG. 2C, the plurality of first block select plugs BSP1 may be separately connected to two of first block select lines BSL1. According to embodiments, two first block select plugs BSP1 connected to one memory cell string MS may be respectively connected to different first block select lines BSL1. For example, a connection relationship between the plurality of second block select plugs BSP2 and the plurality of second block select lines BSL2 may be similar to a connection relationship between the plurality of first block select plugs BSP1 and the plurality of first block select lines BSL1 described herein.

According to embodiments, the plurality of first gate plugs VGP1 may be separately connected to two of first horizontal word lines LWL1. For example, two first gate plugs VGP1 connected to one memory cell string MS may be respectively connected to different first horizontal word lines LWL1. A connection relationship between the plurality of second gate plugs VGP2 and the plurality of second horizontal word lines LWL2, . . . , a connection relationship between the plurality of n-th gate plugs VGPn and the plurality of n-th horizontal word lines LWLn may be similar to a connection relationship between the plurality of first gate plugs VGP1 and the plurality of first horizontal word lines LWL1.

Referring to FIG. 2D, the plurality of first multi-select plugs MSP1 may be respectively connected to the plurality of first multi-select lines MSL1, and the plurality of second multi-select plugs MSP2 may be respectively connected to the plurality of second multi-select lines MSL2.

Referring to FIG. 2E and FIG. 2B, each of the plurality of memory cell string columns MSC may be connected to a first common source plug CSP1 or a second common source plug CSP2. One of a plurality of first common source plugs CSP1 and one of a plurality of second common source plugs CSP2 are illustrated in FIG. 2E, and the others are omitted. For example, one memory cell string column MSC may share one common source plug. According to embodiments, the plurality of first common source plugs CSP1 and the plurality of second common source plugs CSP2 may be connected to different common source lines CSL. For example, the plurality of first common source plugs CSP1 may be connected to a first common source line CSL1, and the plurality of second common source plugs CSP2 may be connected to a second common source line CSL2.

Referring to FIG. 2F, each of the plurality of memory cell strings MS may have two drain areas. The two drain areas may be connected to the same bit line pad BP. According to embodiments, some of the plurality of memory cell strings MS may share one bit line pad BP.

According to embodiments, each of the plurality of bit line pads BP may be connected to a plurality of bit line plugs BLP respectively. The plurality of the bid line pads BP may be connected to the plurality of bit lines BL through the plurality of bit line plugs BLP.

FIG. 3A is a perspective view illustrating a representative configuration of a memory device 100 according to an embodiment. FIG. 3B is a plan view illustrating a cell array structure CS of the memory device 100 according to an embodiment. FIG. 3C is a plan view illustrating a main configuration of a peripheral circuit structure PS of the memory device 100 according to an embodiment.

Referring to FIG. 3A, FIG. 3B, and FIG. 3C, the memory device 100 may include a cell array structure CS and a peripheral circuit structure PS that overlap each other in a vertical direction. The peripheral circuit structure PS may be interposed between the substrate (not shown) and the cell array structure CS. The cell array structure CS may include the memory cell array 20 described with reference to FIG. 1, and the peripheral circuit structure PS may include the peripheral circuit 30 described with reference to FIG. 1.

As illustrated in FIG. 3B, the cell array structure CS may include a plurality of memory cell blocks BLK1, BLK2, . . . , BLKn. Each of the plurality of memory cell blocks BLK1, BLK2, . . . , BLKn may include three-dimensionally arranged memory cells.

According to embodiments, the plurality of memory cell blocks BLK1, BLK2, . . . , BLKn may be disposed in a first horizontal direction (the X direction), and each of the plurality of memory cell blocks BLK1, BLK2, . . . , BLKn may include a plurality of chunks CHK repeatedly disposed in a second horizontal direction (the Y direction) orthogonal to the first horizontal direction (the X direction).

According to embodiments, a plurality of first bit line pad stacks BPS1 and a plurality of second bit line pad stacks BPS2 may be alternately disposed in the first horizontal direction (the X direction) one by one between the plurality of memory cell blocks BLK1, BLK2, . . . , BLKn. According to embodiments, one chunk CHK may be between one of the plurality of first bit line pad stacks BPS1 and one of the plurality of second bit line pad stacks BPS2 which may be separated from each other in the first horizontal direction (the X direction). For example, the plurality of chunks CHK may be separated from each other in the first horizontal direction (the X direction) with the first bit line pad stack BPS1 or the second bit line pad stack BPS2 therebetween.

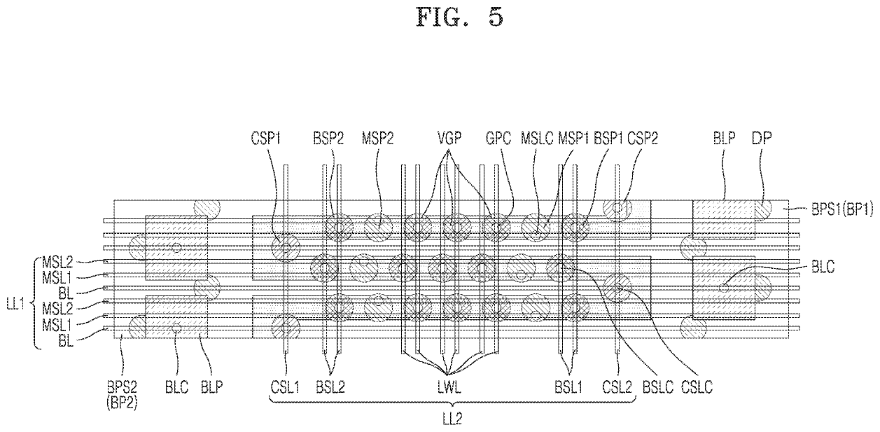

According to embodiments, a plurality of first wires LL1, which cross the plurality of memory cell blocks BLK1, BLK2, . . . , BLKn, the plurality of first bit line pad stacks BPS1, and the plurality of second bit line pad stacks BPS2 and may be elongated in the first horizontal direction (the direction), may be on the plurality of memory cell blocks BLK1, BLK2, . . . , BLKn. According to embodiments, a plurality of second wires LL2 which may be elongated in the second horizontal direction (the Y direction), may be on the plurality of memory cell blocks BLK1, BLK2, . . . , BLKn. Referring to FIGS. 3B and 5, the plurality of second wires LL2 may include a first common source line CSL1, a second common source line CSL2, a plurality of first block select lines BSL1, a plurality of second block select lines BSL2, and a plurality of horizontal word lines LWL. The plurality of first wires LL1 may include a plurality of bit lines BL, a plurality of first multi-select lines MSL1, and a plurality of second multi-select lines MSL2. For example, the plurality of first wires LL1 and the plurality of second wires LL2 may be at different levels in the vertical direction (the Z direction).

As illustrated in FIG. 3C, the peripheral circuit structure PS may include a first circuit area AA1 to be involved in an operation of the cell array structure CS. According to embodiments, in a planar view, the first circuit area AA1 may include a word line decoder area 42, a block select decoder area 44, a page buffer area 41, a multi-select decoder area 43, and a peripheral area 45. The word line decoder area 42 may be an area where a circuit electrically connected to the plurality of horizontal word lines LWL (see for example, FIG. 5) is arranged. The block select decoder area 44 may be an area where a circuit electrically connected to the plurality of first and second block select lines BSL1 and BSL2 (see for example, FIG. 5) is arranged. The page buffer area 41 may be an area where a circuit electrically connected to the plurality of bit lines BL1 and BL2 (see for example, FIG. 5) is arranged. The multi-select decoder area 43 may be an area where a circuit electrically connected to the plurality of first and second multi-select lines MSL1 and MSL2 is arranged. The peripheral area 45 may include an input/output circuit and so on.

According to embodiments, in a planar view, the first circuit area AA1 may include a first area A1, a second area A2, a third area A3, and a fourth area A4, which may be disposed in a counterclockwise direction from an area located at the upper right when the first circuit area AA1 is divided into a quadrant having a first central axis AX1 in the first horizontal direction (the X direction) and a second central axis AX2 in the second horizontal direction (the Y direction). According to embodiments, a point in which the first central axis AX1 intersects the second central axis AX2 may be a first central point that is a center portion of the first circuit area AA1.

According to embodiments, in a planar view, the word line decoder area 42 may be in contact with the second central axis AX2 in the first area A1 and the third area A3 and may be in contact with a part of the first central axis AX1. In some embodiments, the word line decoder area 42 may have a quadrangular planar shape and may be in contact with the second central axis AX2 as a whole.

According to embodiments, in a planar view, the block select decoder area 44 may be in contact with the word line decoder area 42 in the first area A1 and the third area A3 and may be in contact with a part of the first central axis AX1. In some embodiments, the block select decoder area 44 may be separated from the second central axis AX2 in the first horizontal direction (the X direction) with the word line decoder area 42 therebetween. In some other embodiments, the block select decoder area 44 may also be in contact with a part of the second central axis AX2.

According to embodiments, in a planar view, the word line decoder area 42 and the block select decoder area 44 may be in point symmetry with respect to the first central point.

According to embodiments, the peripheral area 45 may be in areas other than the word line decoder area 42 and the block select decoder area 44 in the first area A1 and the third area A3.

According to embodiments, in a planar view, the page buffer area 41 may be in contact with the first central axis AX1 and a part of the second central axis AX2 in the second area A2 and the fourth area A4. In some embodiments, the page buffer area 41 may be in contact with the first central axis AX1 as a whole.

According to embodiments, in a planar view, the multi-select decoder area 43 may be in contact with the page buffer area 41 and a part of the second central axis AX2 in the second area A2 and the fourth area A4. In some embodiments, the multi-select decoder area 43 may be separated from the first central axis AX1 in the second horizontal direction (the Y direction) with the page buffer area 41 therebetween. In some other embodiments, the multi-select decoder area 43 may be in contact with a part of the first central axis AX1.

According to embodiments, in a planar view, the page buffer area 41 and the multi-select decoder area 43 may be in point symmetry with respect to the first central point.

According to embodiments, the peripheral area 45 may be in areas other than the page buffer area 41 and the multi-select decoder area 43 in the second area A2 and the fourth area A4.

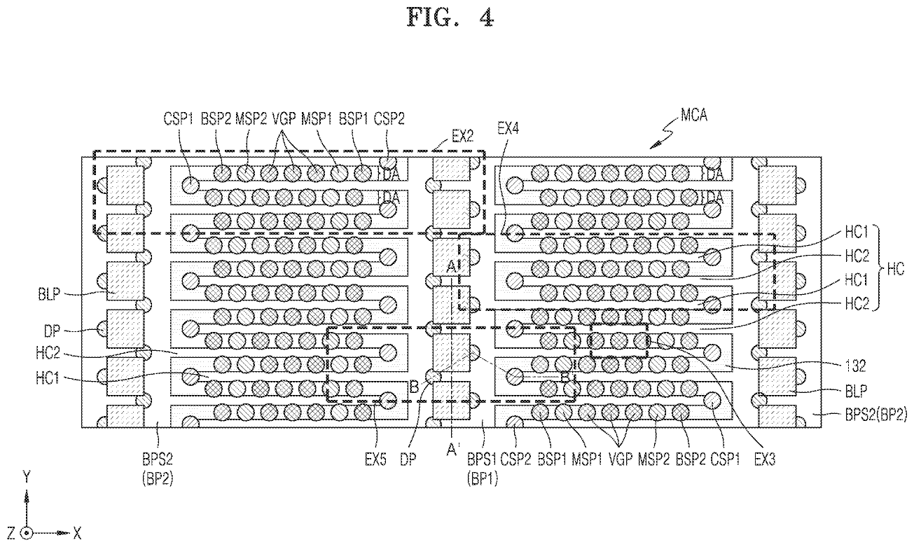

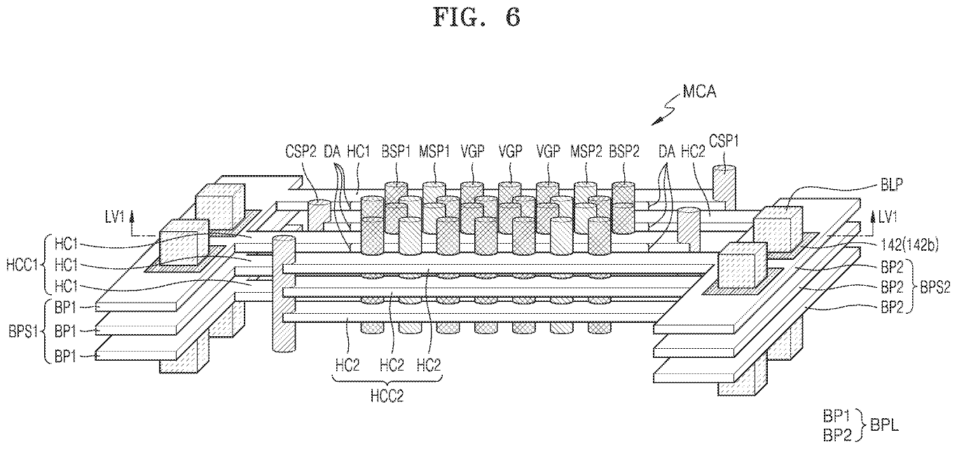

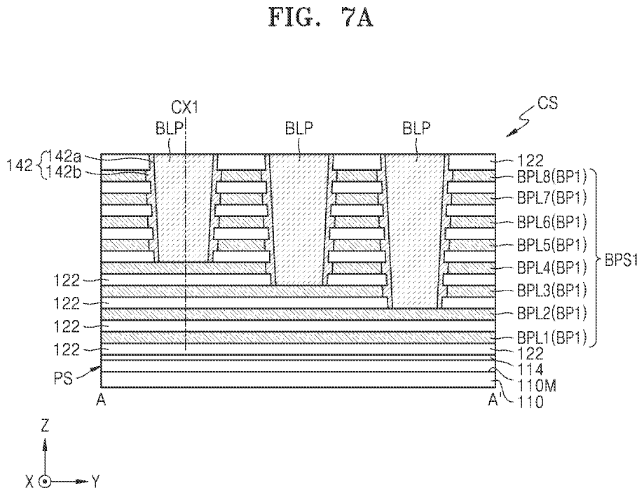

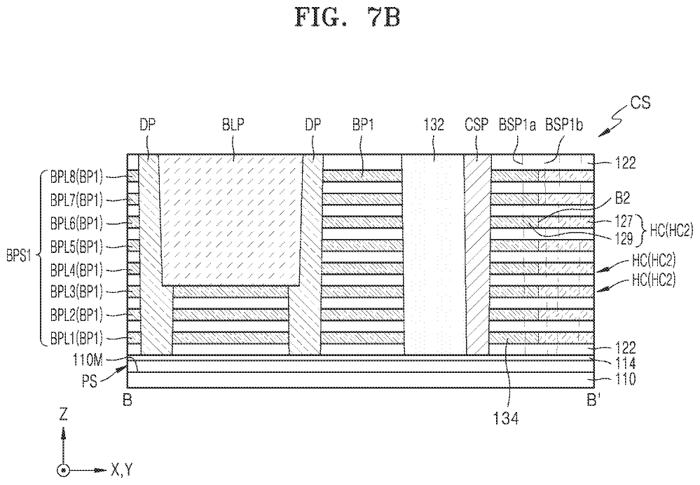

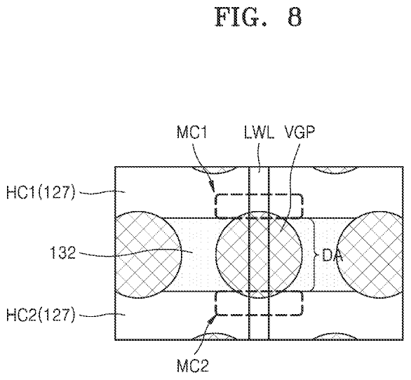

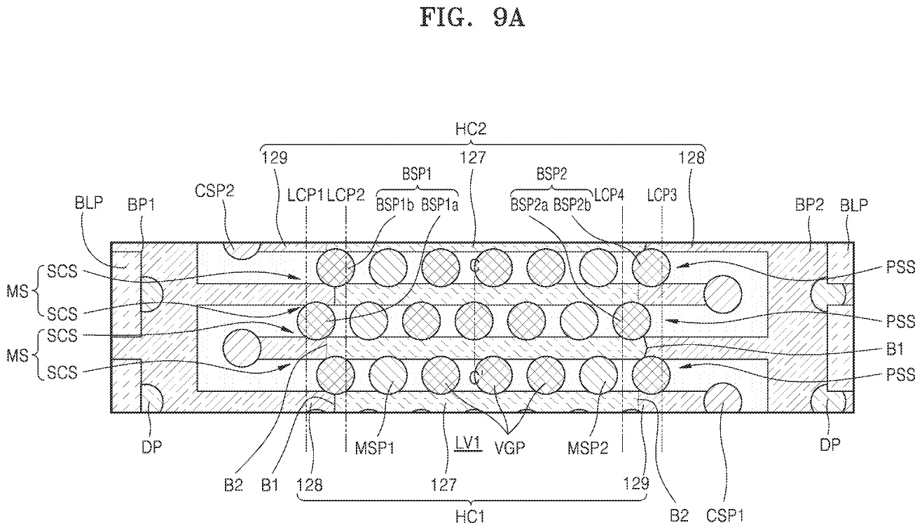

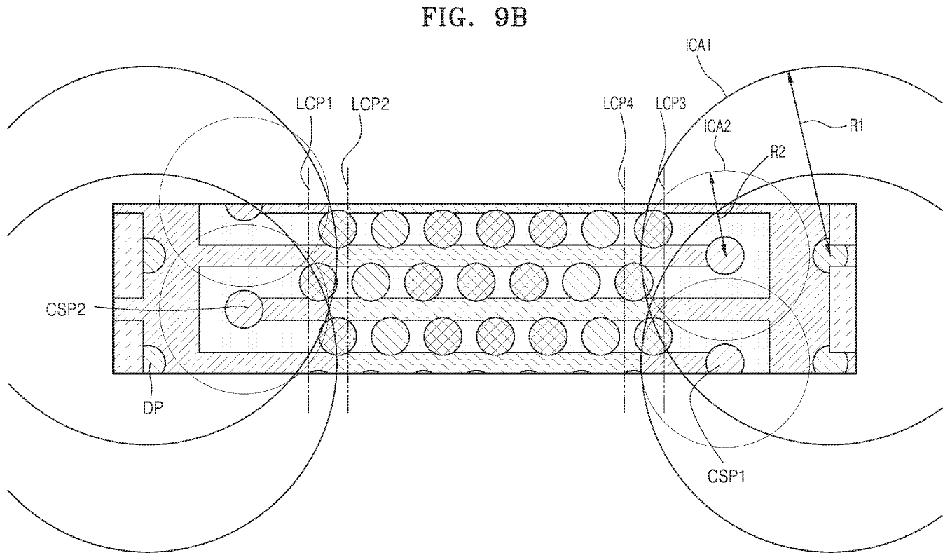

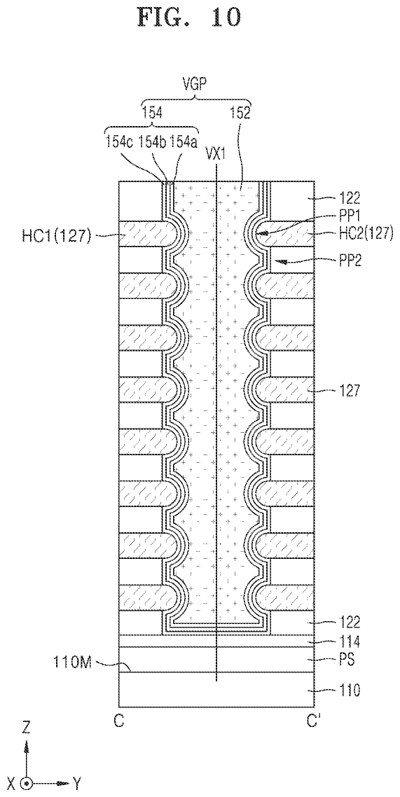

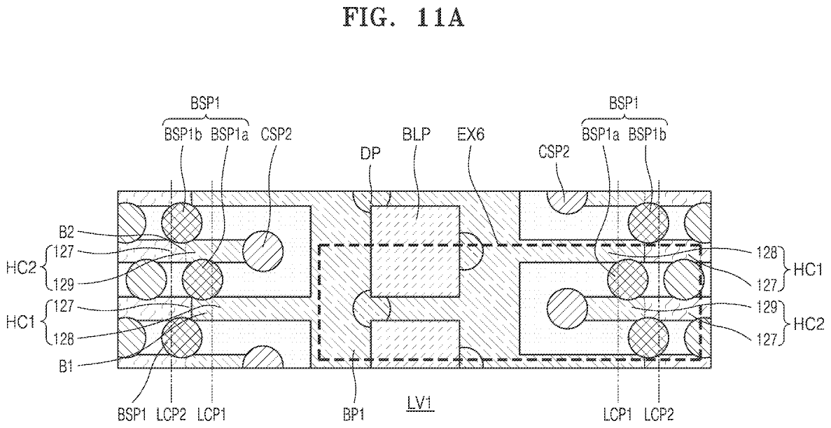

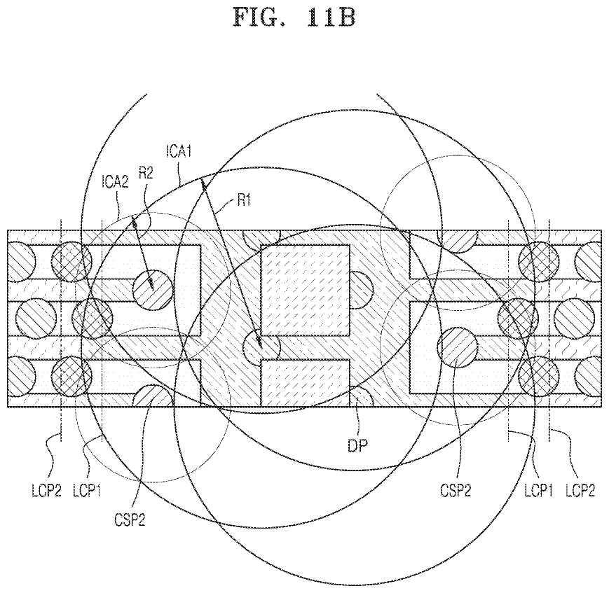

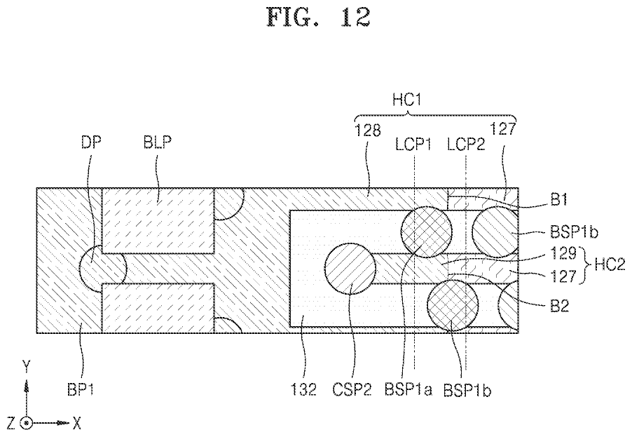

FIG. 4 is a plan view illustrating a main configuration of the memory device 100 and is an enlarged view of an area indicated by “EX1” in FIG. 3B. FIG. 5 is an enlarged view of an area indicated by “EX2” in FIG. 4. FIG. 6 is a perspective view illustrating a main configuration of a memory device 100 according to an embodiment. FIG. 7A is a cross-sectional view taken along line A-A′ of FIG. 4, and FIG. 7B is a cross-sectional view taken along line B-B′ of FIG. 4. FIG. 8 is an enlarged view of an area indicated by “EX3” in FIG. 4, and FIG. 9 is an enlarged view of an area indicated by “EX4” in FIG. 4. FIG. 10 is a cross-sectional view taken along line C-C′ of FIG. 9. FIG. 11 is an enlarged view of an area indicated by “EX5” in FIG. 4, and FIG. 12 is an enlarged view of an area indicated by “EX6” in FIG. 11. Specifically, FIG. 8, FIG. 9, FIG. 11, and FIG. 12 are plan views illustrating a configuration of the memory device 100 illustrated in FIG. 6 at the first vertical level LV1.

Hereinafter, the cell array structure CS of the memory device 100 according to embodiments are described in detail with reference to FIGS. 4 to 12.

Referring to FIGS. 4 to 12, the memory device 100 may include the peripheral circuit structure PS and the cell array structure CS sequentially stacked on a substrate 110 having a main surface 110M. The peripheral circuit structure PS may be interposed between the substrate 110 and the cell array structure CS. In the accompanying drawings, a size of the peripheral circuit structure PS is reduced for the sake of convenience of illustration. Although not illustrated in the accompanying drawings, the peripheral circuit structure PS may include a plurality of peripheral circuit transistors (not illustrated), a device isolation film (not illustrated), and a peripheral circuit wiring structure (not illustrated) disposed on the substrate 110.

According to embodiments, the substrate 110 may include a semiconductor material, and the semiconductor material may include a group IV semiconductor, a group III-V compound semiconductor, or a group II-VI oxide semiconductor. For example, the group IV semiconductor may include silicon (Si), germanium (Ge), or silicon-germanium. In some embodiments, substrate 110 may be provided as a bulk wafer or an epitaxial layer. In some other embodiments, the substrate 110 may include a silicon-on-insulator (SOI) substrate or a germanium-on-insulator (GeOI) substrate.

As illustrated in FIG. 7A and FIG. 7B, an etch stop layer 114 may be between the cell array structure CS and the peripheral circuit structure PS. According to embodiments, the etch stop layer 114 may include an aluminum oxide layer, but is not limited thereto.

According to embodiments, the cell array structure CS may include the plurality of first bit line pad stacks BPS1 and the plurality of second bit line pad stacks BPS2 separated from each other in the first horizontal direction (the X direction) parallel to the main surface 110M of the substrate 110. According to embodiments, the plurality of first bit line pad stacks BPS1 and the plurality of second bit line pad stacks BPS2 may extend in the second horizontal direction (the Y direction).

According to embodiments, each of the plurality of first bit line pad stacks BPS1 may include a plurality of first bit line pads BP1 overlapping each other at positions separated from each other in the vertical direction (the Z direction). According to embodiments, each of the plurality of second bit line pad stacks BPS2 may include a plurality of second bit line pads BP2 overlapping each other at positions separated from each other in the vertical direction (the Z direction). According to embodiments, a plurality of interlayer insulating layers 122 may be respectively disposed between the plurality of first bit line pads BP1 separated from each other in the vertical direction (the Z direction) and between the plurality of second bit line pads BP2 separated from each other in the vertical direction (the Z direction).

According to embodiments, the plurality of first bit line pads BP1 and the plurality of second bit line pads BP2 may each be formed of doped polysilicon. In some embodiments, the plurality of first bit line pads BP1 and the plurality of second bit line pads BP2 may each be formed of polysilicon doped with an n-type dopant. For example, the n-type dopant may be selected from phosphorus (P), arsenic (As), or antimony (Sb). In some other embodiments, the plurality of first bit line pads BP1 and the plurality of second bit line pads BP2 may each be formed of polysilicon doped with a p-type dopant. For example, the p-type dopant may be selected from boron (B) or gallium (Ga).

According to embodiments, the plurality of first bit line pads BP1 and the plurality of second bit line pads BP2 disposed at a same vertical level may configure one bit line pad layer (for example, a first bit line pad layer BPL1). According to embodiments, a plurality of bit line pad layers BPL1, BPL2, . . . , BPL8 and the plurality of interlayer insulating layers 122 may be alternately stacked in the vertical direction (the Z direction). For example, a set of the plurality of first bit line pad stacks BPS1 and the plurality of second bit line pad stacks BPS2 may configure the plurality of bit line pad layers BPL1, BPL2, . . . , BPL8 overlapping each other in the vertical direction (the Z direction). As used herein, the “vertical level” indicates a distance in the vertical direction (the Z direction or the −Z direction) from the main surface 110M of the substrate 110.

Although FIG. 7A and FIG. 7B illustrate that the memory device 100 includes eight bit line pad layers BPL1, BPL2, . . . , BPL8, the inventive concept is not limited thereto. For example, the memory device 100 may include seven or less bit line pad layers, for example, four bit line pad layers or may include nine or more bit line pad layers.

According to embodiments, a plurality of horizontal channel areas HC may be between the plurality of first bit line pad stacks BPS1 and the plurality of second bit line pad stacks BPS2. The plurality of horizontal channel areas HC may extend parallel to each other along the first horizontal direction (the X direction), and may be connected to the first bit line pad BP1 or to the second bit line pad BP2 at the same vertical level as each of the plurality of horizontal channel areas HC. According to embodiments, a first group of horizontal channel areas HC may be spaced apart from each other along a second horizontal direction (the Y direction) perpendicular to the first horizontal direction (the X direction). According to embodiments, a second group of horizontal channel areas HC may be spaced apart from each other and overlap each other in the vertical direction (the Z direction). A plurality of interlayer insulating layers 122 may be disposed between the second group of horizontal channel areas HC spaced apart from each other in the vertical direction (the Z direction).

According to embodiments, the plurality of horizontal channel areas HC may be formed of undoped polysilicon, doped polysilicon, a compound semiconductor material, an oxide semiconductor material, a two-dimensional semiconductor material, or a combination thereof. The compound semiconductor material may be selected from a group IV compound semiconductor, a group IV-IV compound semiconductor, a group III-V compound semiconductor, a group II-VI compound semiconductor, or a group IV-VI compound semiconductor. The group IV compound semiconductor may be selected from Si or Ge. The group IV-IV compound semiconductor may be selected from SiGe, SiC, SiGeC, GeSn, SiSn, or SiGeSn. The group III-V compound semiconductor may be composed of a compound semiconductor including at least one of In, Ga, or Al as a group III element and at least one of As, P, or Sb as a group V element. The group III-V compound semiconductor may be composed of a binary, ternary, or quaternary compound including 2, 3, or 4 elements selected from a group III element or a group V element. Herein, the materials listed herein may indicate materials composed of elements included in each term and may not be chemical formulas showing a stoichiometric relationship.

According to embodiments, the plurality of horizontal channel areas HC may include a plurality of first horizontal channel areas HC1 connected to the plurality of first bit line pads BP1 and a plurality of second horizontal channel areas HC2 connected to the plurality of second bit line pads BP2.

According to embodiments, in a planar view, the plurality of first horizontal channel areas HC1 and the plurality of second horizontal channel areas HC2 may be disposed alternately in the second horizontal direction (the Y direction).

In some embodiments, a first end portion of a first group of first horizontal channel areas HC1 disposed at a same vertical level among the plurality of first horizontal channel areas HC1, may be connected to a first bit line pad of the plurality of first bit line pads BP1 at the same vertical level as the first group of first horizontal channel areas HC1. For example, the first group of first horizontal channel areas HC1 may share the first bit line pad BP1. In this case, a second end portion of the first group of first horizontal channel areas HC1 in the first horizontal direction (the X direction) may be spaced apart from a second bit line pad of the plurality of second bit line pads BP2 in the first horizontal direction (the X direction) at a same vertical level as the first group of first horizontal channel areas HC1.

In some embodiments, a first end portion of a first group of second horizontal channel areas HC2 disposed at a same vertical level among the plurality of second horizontal channel areas HC2, may be connected to a second bit line pad of the plurality of second bit line pads BP2 at the same vertical level as the first group of second horizontal channel areas HC2. For example, the first group of second horizontal channel areas HC2 may share the second bit line pad BP2. In this case, a second end portion of the first group of second horizontal channel areas HC2 in the first horizontal direction (the X direction) may be spaced apart from a first bit line pad of the plurality of first bit line pads BP1 in the first horizontal direction (the X direction) at the same vertical level as the first group of second horizontal channel areas HC2.

In some embodiments, the first group of first horizontal channel areas HC1 and the first group of second horizontal channel areas HC2 may constitute a horizontal channel layer, and in this case, the memory device 100 may include a plurality of horizontal channel layers overlapping each other at positions spaced apart from each other in the vertical direction (the Z direction).

According to embodiments, the plurality of first horizontal channel areas HC1 may include second group of first channel areas HC1 each overlapping each other in the vertical direction (the Z direction) at positions spaced apart from each other. The plurality of second horizontal channel areas HC2 may include second group of second channel areas HC2 each overlapping each other in the vertical direction (the Z direction) at positions spaced apart from each other.

According to embodiments, the second group of first horizontal channel areas HC1 may overlap each other in the vertical direction (the Z direction) at a plurality of vertical levels, and the second group of second horizontal channel areas HC2 may overlap each other in the vertical direction (the Z direction) at the plurality of vertical levels. According to embodiments, among the plurality of first horizontal channel areas HC1, the second group of first horizontal channel areas HC1 may constitute a first channel column HCC1, and among the plurality of second horizontal channel areas HC2, the second group of second horizontal channel areas HC2 may constitute a second channel column HCC2. According to embodiments, each of a plurality of first channel columns HCC1 may be connect to the first bit line stack BPS1 and each of a plurality of second channel columns HCC2 may be connected to the second bit line pad stack BPS2. The plurality of first channel columns HCC1 and the plurality of second channel columns HCC2 may be alternately disposed in the second horizontal direction (the Y direction).

For example, first bit line pads BP1 of the first bit line stack BPS1 may be disposed at the plurality of vertical levels, and second bit line pads BP2 of the second bit line stack BPS2 may be disposed at the plurality of vertical levels. In some embodiments, first channel areas HC1 of the first channel column HCC1 may be in contact with a corresponding one of the first bit line pads BP1 at a corresponding vertical level of the plurality of the vertical level. Second channel areas HC2 of the second channel column HCC2 may be in contact with a corresponding one of the second bit line pads BP2 at a corresponding vertical level of the plurality of the vertical level.

In some embodiments, a plurality of isolation areas DA may be between the plurality of first channel columns HCC1 and the plurality of second channel columns HCC2 separated from each other in the second horizontal direction (the Y direction). For example, in a planar view, the plurality of first horizontal channel areas HC1 and the plurality of second horizontal channel areas HC2 may be spaced apart from each other in the second horizontal direction (the Y direction) with the plurality of isolation areas DA therebetween.

According to embodiments, a first structure including the plurality of first bit line pad stacks BPS1 and the plurality of first horizontal channel areas HC1 connected thereto, and a second structure including the plurality of second bit line pad stacks BPS2 and the plurality of second horizontal channel areas HC2 connected thereto may be defined, and an insulating pattern structure 132 may be between the first structure and the second structure. According to embodiments, the first structure and the second structure may have an interdigitated structure with the insulating pattern structure 132 therebetween. For example, the insulating pattern structure 132 may be in the plurality of isolation areas DA.

According to embodiments, a sidewall of the insulating pattern structure 132 may include a portion in contact with the plurality of horizontal channel areas HC, a portion in contact with the plurality of first bit line pad stacks BPS1, a portion in contact with the plurality of second bit line pad stacks BPS2, and a portion in contact with the plurality of interlayer insulating layers 122.

For example, the plurality of first horizontal channel areas HC1 may be separated from the plurality of second horizontal channel areas HC2 in the second horizontal direction (the Y direction) with the insulating pattern structure 132 therebetween. For example, the plurality of first horizontal channel areas HC1 may be separated from the plurality of second bit line pad stacks BPS2 in the first horizontal direction (the X direction) with the insulating pattern structure 132 therebetween. For example, the plurality of second horizontal channel areas HC2 may be separated from the plurality of first bit line pad stacks BPS1 in the first horizontal direction (the X direction) with the insulating pattern structure 132 therebetween.

According to embodiments, the insulating pattern structure 132 may be formed of a material with etch selectivity with respect to configuration materials of the plurality of interlayer insulating layers 122. In non-limiting embodiments, the plurality of interlayer insulating layers 122 may be formed of a silicon oxide film, and the insulating pattern structure 132 may be formed of a silicon nitride film.

According to embodiments, a second end portion of each of the plurality of first horizontal channel areas HC1 may be in contact with a plurality of first common source plugs CSP1 extending in the vertical direction (the Z direction) passing through the insulating pattern structure 132. According to embodiments, each of the plurality of first common source plugs CSP1 may contact the plurality of first horizontal channel areas HC1 overlapping each other in the vertical direction (the Z direction). For example, a first end portion of each of the plurality of first channel columns HCC1 may contact a first bit line pad stack BPS1, and a second end portion thereof may contact a first common source plug CSP1. For example, each of the plurality of first channel columns HCC1 may share a first common source plug CSP1.

For example, the plurality of first bit line pads BP1 at different vertical levels overlapped each other may be connected to a first common source plug CSP1 through the plurality of first horizontal channel areas HC1 in contact with the plurality of first bit line pads BP1.

According to embodiments, the plurality of first common source plugs CPS1 may be disposed in the second horizontal direction (the Y direction) and separated from each other with each of the plurality of second horizontal channel areas HC2 therebetween. According to embodiments, the plurality of first common source plugs CPS1 may be separated from the plurality of second bit line pads BP2 in the first horizontal direction (the X direction) with the insulating pattern structure 132 therebetween.

According to embodiments, second end portions of the plurality of second horizontal channel areas HC2 may be in contact with a plurality of second common source plugs CSP2 extending in the vertical direction (the Z direction) passing through the insulating pattern structure 132. According to embodiments, each of the plurality of second common source plugs CPS2 may contact the plurality of second horizontal channel areas HC2 overlapping each other in the vertical direction (the Z direction). For example, a first end portion of each of the plurality of second channel columns HCC2 may contact a second bit line pad stack BPS2, and a second end portion thereof may contact a second common source plug CSP2. For example, each of the plurality of second channel columns HCC2 may share a second common source plug CSP2.

For example, the plurality of second bit line pads BP2 at different vertical levels overlapped each other may be connected to a second common source plug CSP2 through the plurality of second horizontal channel areas HC2 in contact with the plurality of second bid line pads BP2.

According to embodiments, the plurality of second common source plugs CPS2 may be disposed in the second horizontal direction (the Y direction) and separated from each other with each of the plurality of first horizontal channel areas HC1 therebetween. According to embodiments, the plurality of second common source plugs CPS2 may be separated from the plurality of first bit line pads BP1 in the first horizontal direction (the X direction) with the insulating pattern structure 132 therebetween.

According to embodiments, each of the plurality of first common source plugs CPS1 may have a portion in contact with the plurality of first horizontal channel areas HC1, a portion in contact with the plurality of interlayer insulating layers 122, and a portion in contact with the insulating pattern structure 132. According to embodiments, each of the plurality of second common source plugs CPS2 may include a portion in contact with the plurality of second horizontal channel areas HC2, a portion in contact with the plurality of interlayer insulating layers 122, and a portion in contact with the insulating pattern structure 132.

Referring to FIG. 5, the plurality of first common source lines CSL1 elongated parallel to each other in the second horizontal direction (the Y direction) may be over the plurality of first common source plugs CSP1. According to embodiments, the plurality of first common source plugs CSP1 may be connected to the plurality of first common source lines CSL1 through a plurality of common source contacts CSLC. For example, among the plurality of first common source plugs CSP1, a first group of first common source plugs CSP1 in a memory cell block may be connected to a first common source line CSL1. For example, the first group of first common source plugs CSP1 may be disposed in a line in the second horizontal direction (the Y direction).

Referring to FIG. 5, the plurality of second common source lines CSL2 elongated parallel to each other in the second horizontal direction (the Y direction) may be over the plurality of second common source plugs CSP2. According to embodiments, the plurality of second common source plugs CSP2 may be connected to the plurality of second common source lines CSL2 through a plurality of common source contacts CSLC. For example, among the plurality of second common source plugs CSP2, a second group of second common source plugs CSP2 in a memory cell block may be connected to a second common source line CSL2. For example, the first group of second common source plugs CSP2 may be disposed in a line in the second horizontal direction (the Y direction).

According to embodiments, one first common source line CSL1 and one second common source line CSL2 may be on a memory cell block. According to embodiments, the plurality of first common source lines CSL1 and the plurality of second common source lines CSL2 may be spaced apart from each other in the first horizontal direction (the X direction) at the same vertical level.

According to embodiments, the plurality of first common source plugs CPS1 and the plurality of second common source plugs CPS2 may be formed of metal, conductive metal nitride, a conductive semiconductor material, or a combination thereof. For example, the plurality of first common source plugs CPS1 and the plurality of second common source plugs CPS2 may be formed of W, Al, Cu, Co, Mo, Ti, Ta, TIN, TaN, WN, WCN, TiSiN, TaSIN, or WSiN, or a combination thereof. The plurality of first common source plugs CPS1 and the plurality of second common source plugs CPS2 are not limited thereto.

According to embodiments, a plurality of gate plugs VGP, which extend in the vertical direction (the Z direction) passing through the insulating pattern structure 132 may be between the plurality of first channel columns HCC1 and the plurality of second channel columns HCC2. According to embodiments, the plurality of gate plugs VGP may be separated from each other in the horizontal direction (the X direction and/or the Y direction). For example, the plurality of gate plugs VGP may be separated from each other in the first horizontal direction (the X direction) in the plurality of isolation areas DA with the insulating pattern structure 132 therebetween. For example, the plurality of gate plugs VGP may be separated from each other in the second horizontal direction (the Y direction) with the first channel column HCC1 or the second channel column HCC2 therebetween.

Although FIG. 4, FIG. 5, FIG. 6, FIG. 9A, and FIG. 9B illustrate that three gate plugs VGP may be disposed in an isolation area DA, the inventive concept is not limited thereto. For example, one, two, four, or more gate plugs VGP may be disposed in the first horizontal direction in an isolation area DA.

In some embodiments, the plurality of gate plugs VGP may be disposed in a line in the first horizontal direction (the X direction) in each of the plurality of isolation areas DA. In some embodiments, in a planar view, two gate plugs VGP, which may be separated from each other in the second horizontal direction (the Y direction) by a horizontal channel area of the plurality of horizontal channel areas HC, may not be disposed on a straight line in the second horizontal direction (the Y direction). According to embodiments, in a planar view, the plurality of gate plugs VGP may be disposed in a zigzag pattern in the second horizontal direction (the Y direction). Accordingly, it may be possible to obtain a margin sufficient to enable adjacent gate plugs VGP to be in contact with different horizontal word lines LWL with a horizontal channel area HC therebetween.

Referring to FIG. 5, the plurality of horizontal word lines LWL elongated parallel to each other in the second horizontal direction (the Y direction) may be disposed over the plurality of gate plugs VGP. Each of the plurality of gate plugs VGP may be electrically connected to the plurality of horizontal word lines LWL through the plurality of gate plug contacts GPC.

A first horizontal word line LWL selected from among the plurality of horizontal word lines LWL may be connected to a first group of gate plugs VGP disposed in a straight row in the second horizontal direction (the Y direction) among the plurality of gate plugs VGP. A second horizontal word line LWL, which is selected from among the plurality of horizontal word lines LWL and adjacent to the first horizontal word line LWL, may be separated from the first group of gate plugs VGP and may be connected to a second group of gate plugs VGP disposed in a straight row in the second horizontal direction (the Y direction). The first group of gate plugs VGP and the second group of gate plugs VGP may be separated from each other in the second horizontal direction (the Y direction) with the plurality of channel columns therebetween.

According to embodiments, each of the plurality of gate plugs VGP may be respectively in contact with the plurality of first horizontal channel areas HC1 and the plurality of second horizontal channel areas HC2 adjacent to each other in the second horizontal direction (the Y direction). For example, as illustrated in FIG. 6, a first end portion of each of the plurality of gate plugs VGP in the second horizontal direction (the Y direction) may be connected to one first channel column HCC1, and a second end portion thereof in the second horizontal direction (the Y direction) may be connected to one second channel column HCC2.

The memory device 100 according to embodiments may have a double cell structure in which two memory cells may be formed by a gate plug VGP in a planar view. As illustrated in FIG. 8, in a planar view, a first end portion of gate plug VGP in the second horizontal direction (the Y direction) may be in contact with the first horizontal channel area HC1 to constitute a first memory cell MC1, and a second end portion thereof may be in contact with the second horizontal channel area HC2 to constitute a second memory cell MC2. According to embodiments, each of the plurality of gate plugs VGP may extend in the vertical direction (the Z direction) and constitute a plurality of double cells which may be separated from each other in the vertical direction (the Z direction) and overlap each other. In this case, the plurality of double cells may be at different vertical levels.

As illustrated in FIG. 6, a gate plug VGP may be in contact with the plurality of first horizontal channel areas HC1 at different vertical levels and the plurality of second horizontal channel areas HC2 at different vertical levels and may constitute two memory cells MC1 and MC2 at each vertical level. For example, as illustrated in FIG. 7B, eight second horizontal channel areas HC2 may overlap each other in the vertical direction (the Z direction), and although not illustrated in FIG. 7B, eight first horizontal channel areas HC1 may overlap each other in the vertical direction (the Z direction). In this case, a first side of one gate plug VPG may be in contact with eight first horizontal channel areas HC1, which may constitute eight first memory cells MC1, and a second side thereof may be in contact with the eight second horizontal channel areas HC2, which may constitute eight second memory cells MC2, and accordingly, a total of sixteen memory cells may be constituted.

This structure may be equally applied to the plurality of gate plugs VGP. According to embodiments, the plurality of memory cells MC1 and MC2 may be repeatedly disposed in the first horizontal direction (the X direction), the second horizontal direction (the Y direction), and the vertical direction (the Z direction) to constitute a memory cell array MCA.

According to embodiments, each of the plurality of gate plugs VGP may include a plug body 152 extending in the vertical direction (the Z direction) and a plug insulating layer 154 surrounding the plug body 152. As illustrated in FIG. 10, the plug body 152 may face the plurality of horizontal channel areas HC with the plug insulating layer 154 therebetween. According to embodiments, each of the plurality of gate plugs VGP may include a first portion PP1 in contact with the plurality of horizontal channel areas HC and a second portion PP2 in contact with the plurality of interlayer insulating layers 122. According to embodiments, the second portion PP2 may protrude from a central axis VX1 in the second horizontal direction (the Y direction) more than the first portion PP1.

According to embodiments, the plug insulating layer 154 may include a blocking dielectric layer 154a, a charge storage layer 154b, and a tunneling dielectric layer 154c sequentially stacked on a bottom wall and an outer wall of the plug body 152. In embodiments, the blocking dielectric layer 154a may include silicon oxide, hafnium oxide, aluminum oxide, zirconium oxide, tantalum oxide, or so on. The charge storage layer 154b may store electrons passing through the blocking dielectric layer 154a from the plug body 152 and may include silicon nitride, boron nitride, silicon boron nitride, or polysilicon doped with a dopant. The tunneling dielectric layer 154c may be formed of silicon oxide, silicon nitride, or metal oxide with higher permittivity than the silicon oxide. The metal oxide may be formed of hafnium oxide, aluminum oxide, zirconium oxide, tantalum oxide, or a combination thereof.

According to embodiments, the memory device 100 may include the plurality of first multi-select plugs MSP1 and the plurality of second multi-select plugs MSP2 separated from each other in the first horizontal direction (the X direction) with the plurality of gate plugs VGP therebetween. According to embodiments, the plurality of first multi-select plugs MSP1 and the plurality of second multi-select plugs MSP2 may have structures similar to structures of the plurality of gate plugs VGP. For example, the plurality of first multi-select plugs MSP1 and the plurality of second multi-select plugs MSP2 may extend in the vertical direction (the Z direction) passing through the insulating pattern structure 132 in the plurality of isolation areas DA. For example, a first end portion of each of the plurality of first multi-select plugs MSP1 in the second horizontal direction (the Y direction) may be in contact with one first channel column HCC1, and a second end portion thereof may be in contact with one second channel column HCC2, such that each of the plurality of first multi-select plugs MSP1 constitute double transistors, which may be stacked in the vertical direction (the Z direction). A first end portion of each of the plurality of second multi-select plugs MSP2 in the second horizontal direction (the Y direction) may be in contact with one first channel column HCC1 and a second end portion thereof may be in contact with one second channel column HCC2, such that each of the plurality of second multi-select plugs MSP2 constitute double transistors, which may be stacked in the vertical direction (the Z direction). For example, the plurality of first multi-select plugs MSP1 and the plurality of second multi-select plugs MSP2 may each include a plug body (not illustrated) and a plug insulating layer (not illustrated).

According to embodiments, the plurality of first multi-select plugs MSP1 may be in contact with the plurality of first horizontal channel areas HC1 at a position closer to the first bit line pad stack BPS1 than the plurality of gate plugs VGP from a relative point of view. According to embodiments, the plurality of second multi-select plugs MSP2 may be in contact with the plurality of second horizontal channel areas HC2 at a position relatively closer to the second bit line pad stack BPS2 than the plurality of gate plugs VGP from a relative point of view.

According to embodiments, the plurality of first multi-select plugs MSP1 may be disposed in the plurality of isolation areas DA, and may be spaced apart from each other along the second horizontal direction (the Y direction). The plurality of second multi-select plugs MSP2 may be arranged one by one in the plurality of isolation areas DA, and may be spaced apart from each other along the second horizontal direction (the Y direction). According to embodiments, in a planar view, the plurality of first multi-select plugs MSP1 may be arranged in a zigzag pattern along the second horizontal direction (the Y direction) with each of the plurality of horizontal channel areas HC therebetween, and the plurality of second multi-select plugs MSP2 may be arranged in a zigzag pattern along the second horizontal direction (the Y direction) with each of the plurality of horizontal channel areas HC therebetween.

FIG. 4, FIG. 5, FIG. 6, FIG. 8, 9A, 9B, FIGS. 10, 11A, and 11B illustrate that the plurality of first multi-select plugs MSP1 and the plurality of second multi-select plugs MSP2 may be respectively arranged in the plurality of isolation areas DA. It should be understood that the inventive concept is not limited thereto. For example, the plurality of first multi-select plugs MSP1 and the plurality of second multi-select plugs MSP2 may be arranged in each of the plurality of isolation areas DA. For example, two, three, four, or more first multi-select plugs MSP1 may be in each of the plurality of isolation areas DA. For example, two, three, four, or more second multi-select plugs MSP2 may be in each of the plurality of isolation areas DA independently of the plurality of first multi-select plugs MSP1.

Referring to FIG. 5, the plurality of first multi-select lines MSL1 and the plurality of second multi-select lines MSL2, which may be elongated parallel in the first horizontal direction (the X direction), may be arranged over the plurality of first multi-select plugs MSP1 and the plurality of second multi-select plugs MSP2.

According to embodiments, each of the plurality of first multi-select lines MSL1 may be connected to the plurality of first multi-select plugs MSP1 that may be arranged in different memory cell blocks and arranged in a line in the first horizontal direction (the X direction). According to embodiments, each of the plurality of second multi-select lines MSL2 may be connected to the plurality of second multi-select plugs MSP2 that may be arranged in different memory cell blocks and arranged in a line in the first horizontal direction (the X direction).

According to embodiments, each of the plurality of first multi-select plugs MSP1 may be connected to the first multi-select line MSL1 through the multi-select line contact MSLC, and each of the plurality of second multi-select plugs MSP2 may be connected to the second multi-select line MSL2 through the multi-select line contact MSLC.

According to embodiments, the memory device 100 may include the plurality of first block select plugs BSP1 and the plurality of second block select plugs BSP2 separated from each other in the first horizontal direction (the X direction) with the plurality of gate plugs VGP, the plurality of first multi-select plugs MSP1, and the plurality of second multi-select plugs MSP2 therebetween. According to embodiments, the plurality of first block select plugs BSP1 and the plurality of second block select plugs BSP2 may have structures similar to structures of the plurality of gate plugs VGP. For example, the plurality of first block select plugs BSP1 and the plurality of second block select plugs BSP2 may extend in the vertical direction (the Z direction) passing through the insulating pattern structure 132 and in the plurality of isolation areas DA. For example, a first end portion of each of the plurality of first block select plugs BSP1 in the second horizontal direction (the Y direction) may be in contact with one first channel column HCC1, and a second end portion thereof may be in contact with one second channel column HCC2, such that each of the plurality of first block select plugs BSP1 constitute double transistors, which may be stacked in the vertical direction (the Z direction). A first end portion of each of the plurality of second block select plugs BSP2 in the second horizontal direction (the Y direction) may be in contact with one first channel column HCC1, and a second end portion thereof may be in contact with one second channel column HCC2, such that each of the plurality of second block select plugs BSP2 constitute double transistors, which may be stacked in the vertical direction (the Z direction). For example, the plurality of first block select plugs BSP1 and the plurality of second block select plugs BSP2 may each include a plug body (not illustrated) and a plug insulating layer (not illustrated).

According to embodiments, the plurality of first block select plugs BSP1 may be arranged one by one in the plurality of isolation areas DA, and may be spaced apart from each other along the second horizontal direction (the Y direction). The plurality of second block select plugs BSP2 may be disposed in the plurality of isolation areas DA, and may be spaced apart from each other along the second horizontal direction (the Y direction). According to embodiments, in a planar view, the plurality of first block select plugs BSP1 may be disposed in a zigzag pattern along the second horizontal direction (the Y direction) with each of the plurality of horizontal channel areas HC therebetween, and the plurality of second block select plugs BSP2 may be disposed in a zigzag pattern along the second horizontal direction (the Y direction) with each of the plurality of horizontal channel areas HC therebetween.

FIG. 4, FIG. 5, FIG. 6, FIG. 8, FIG. 9A, FIG. 9B, FIG. 10, FIG. 11A, and FIG. 11B illustrate that the plurality of first block select plugs BSP1 and the plurality of second block select plugs BSP2 may be respectively disposed in the plurality of isolation areas DA. It should be understood that the inventive concept is not limited thereto. For example, the plurality of first block select plugs BSP1 and the plurality of second block select plugs BSP2 may be disposed in each of the plurality of isolation areas DA. For example, two, three, four, or more first block select plugs BSP1 may be disposed in each of the plurality of isolation areas DA. For example, two, three, four, or more second block select plugs BSP2 may be disposed in each of the plurality of isolation areas DA independently of the plurality of first block select plugs BSP1.

Referring to FIG. 5, the plurality of first block select lines BSL1 may be disposed over the plurality of first block select plugs BSP1, and the plurality of second block select lines BSL2 may be disposed over the plurality of second block select plugs BSP2. According to embodiments, the plurality of first block select plugs BSP1 may be respectively connected to the plurality of first block select lines BSL1 through the plurality of block select line contacts BSLC, and the plurality of second block select plugs BSP2 may be respectively connected to the plurality of second block select lines BSL2 through the plurality of block select line contacts BSLC.

According to embodiments, a first sub-line selected from among the plurality of first block select lines BSL1 may be connected to a first group of first block select plugs BSP1 disposed in a straight line in the second horizontal direction (the Y direction) selected from among the plurality of first block select plugs BSP1. A second sub-line which is selected from the plurality of first block select lines BSL1 and adjacent to the first sub-line, may be separated from the first group of first block select plugs BSP1 in the first horizontal direction (the X direction) and may be connected to a second group of first block select plugs BSP1 disposed in a straight line in the second horizontal direction (the Y direction) selected from among the plurality of first block select plugs BSP1. The first group of first block select plugs BSP1 may be separated from the second group of first block select plugs BSP1 in the second horizontal direction (the Y direction) with the plurality of horizontal channel areas HC therebetween.

According to embodiments, an arrangement of the plurality of second block select lines BSL2 and the plurality of second block select plugs BSP2 may be similar to an arrangement of the plurality of first block select lines BSL1 and the plurality of first block select plugs BSP1.

According to embodiments, the plurality of first block select plugs BSP1 may be in contact with the plurality of first horizontal channel areas HC1 at a position closer to the first bit line pad stack BPS1 than the plurality of gate plugs VGP and the plurality of first multi-select plugs MSP1 from a relative point of view. According to embodiments, the plurality of second block select plugs BSP2 may be in contact with the plurality of second horizontal channel areas HC2 at a position closer to the second bit line pad stack BPS2 than the plurality of gate plugs VGP and the plurality of second multi-select plugs MSP2 from a relative point of view.

According to embodiments, one first block select plug BSP1, one first multi-select plug MSP1, one or more gate plugs VGP, one second multi-select plug MSP2, and one second block select plug BSP2 may be separated from each other in the first horizontal direction (the X direction) in one isolation area DA. For example, a first end portion of one first block select plug BSP1, a first end portion of one first multi-select plug MSP1, a first end portion of each of more gate plugs VGP, a first end portion of one second multi-select plug MSP2, and a first end portion of one second block select plug BSP2 in the second horizontal direction (the Y direction) may be in contact with one first channel column HCC1, and a second end portion thereof may be in contact with one second channel column HCC2. For example, a first block select plug BSP1, a first multi-select plug MSP1, one or more gate plugs VGP, a second multi-select plug MSP2, and a second block select plug BSP2 may constitute one plug strings PSS. For example, a plurality of plug strings PSS may be separated from each other in the second horizontal direction (the Y direction), each having one horizontal channel area HC therebetween.

Although FIG. 4, FIG. 5, FIG. 6, FIG. 8, FIG. 9A, FIG. 9B, FIG. 10, FIG. 11A, and FIG. 11B illustrate that each of the plurality of plug strings PSS may include one first block select plug BSP1, one first multi-select plug MSP1, three gate plugs VGP, one second multi-select plug MSP2, and one second block select plug BSP2, the inventive concept is not limited thereto. For example, each of the plurality of plug strings PSS may include two or more first and second block select plugs BSP1 and BSP2, may include two or more first and second multi-select plugs MSP1 and MSP2 and may include four or more gate plugs VGP.

In embodiments, the memory cell array MCA may include a plurality of cells elongated in the first horizontal direction (the X direction) parallel to the main surface 110M of the substrate 110 on the substrate 110. The plurality of memory cell strings MS may be repeatedly disposed in the second horizontal direction (the Y direction), which may be parallel to the main surface 110M of the substrate 110 and orthogonal to the first horizontal direction (the X direction), and may be repeatedly disposed in the vertical direction (the Z direction) perpendicular to the main surface 110M of the substrate 110. As the memory device 100 according to embodiments has a double cell structure, each of the plurality of memory cell strings MS may include two sub-cell strings SCS. According to embodiments, one side of each of the plurality of memory cell strings MS may be connected to the first bit line pad stack BPS1 or the second bit line pad stack BPS2, and the other side thereof may be connected to the first common source plug CSP1 or the second common source plug CSP2.

According to embodiments, the memory device 100 may include a plurality of dummy plugs DP passing through the plurality of first and second bit line pad stacks BPS1 and BPS2 in the vertical direction (the Z direction). FIG. 4 illustrates that the plurality of dummy plugs DP may be disposed in a zigzag pattern in the second horizontal direction (the Y direction). It should be understood that the inventive concept is not limited thereto. For example, the plurality of dummy plugs DP may be disposed in a straight line in the second horizontal direction (the Y direction).

According to embodiments, each of the plurality of first bit line pad stacks BPS1 and each of the plurality of second bit line pad stacks BPS2 may be respectively connected to the plurality of bit line plugs BLP. For example, the plurality of bit line plugs BLP may extend in the vertical direction (the Z direction) and may have different lengths along the vertical direction (the Z direction).

According to embodiments, the plurality of first bit line pads BP1, which constitute one first bit line pad stack BPS1 and overlap each other in the vertical direction (the Z direction), may respectively individually connected to the plurality of bit line plugs BLP. For example, the plurality of bit line plugs BLP may be respectively individually connected to the plurality of first bit line pads BP1 disposed at different vertical levels. Similarly, the plurality of second bit line pads BP2 at different vertical levels in the vertical direction (the Z direction) may be respectively individually connected to the plurality of bit line plugs BLP.

As illustrated in FIG. 7A, a first bit line plug BLP selected from the plurality of bit line plugs BLP may contact an upper surface of a lower first bit line pad BP1. The first bit line plug BLP may penetrate the interlayer insulating layer 122 having a higher vertical level than the lower first bit line pad BP1, and one or more first bit line pads BP1 having a higher vertical level than the lower first bit line pad BP1. For example, the bit line plug BLP connected to the second bit line pad layer BPL2 selected from among the plurality of bit line plugs BLP may penetrate a plurality of interlayer insulating layers 122 and the third to eighth bit line pad layers BPL3, . . . , BPL8 in the vertical direction (the Z direction) having a higher vertical level than the second bit line pad layer BPL2 and may be in contact with an upper surface of the second bit line pad layer BPL2.

According to embodiments, sidewalls of the plurality of bit line plugs BLP may be covered by the bit line plug insulating layer 142. According to embodiments, the bit line plug insulating layer 142 may have a first portion 142a in contact with the plurality of interlayer insulating layers 122 and a second portion 142b in contact with the plurality of first bit line pads BP1. According to embodiments, each of the plurality of bit line plugs BLP may be separated from the plurality of first bit line pads BP1 with the second portion 142b of the bit line plug insulating layer 142 therebetween.

According to embodiments, the second portion 142b of the bit line plug insulating layer 142 may have a structure protruding more from the sidewall of each of the plurality of bit line plugs BLP than the first portion 142a. For example, a boundary between the second portion 142b and each of the plurality of first bit line pads BP1 may be more outside a plug central axis CX1 than the boundary between the first portion 142a and each of the plurality of interlayer insulating layers 122. For example, the second portion 142b may have a part facing each of the plurality of interlayer insulating layers 122 in the vertical direction (the Z direction).

Although FIG. 7A illustrates the plurality of bit line plugs BLP connected to the first bit line pad stack BPS1 as an example, the second bit line pad stack BPS2 and a plurality of bit line plugs BLP connected to the second bit line pad stack BPS2 may also have a structure similar thereto.

According to embodiments, the plurality of bit line plugs BLP may each be formed of metal, conductive metal nitride, a conductive semiconductor material, or a combination thereof. For example, each of the plurality of bit line plugs BLP may be formed of W, Al, Cu, Co, Mo, Ti, Ta, TiN, TaN, WN, WCN, TiSiN, TaSIN, WSiN, or a combination thereof but is not limited thereto. According to embodiments, the plurality of bit line plug insulating layers 142 may be formed of silicon nitride, and are not limited thereto.

Referring to FIG. 5, the plurality of bit lines BL may extend parallel to each other in the first horizontal direction (the X direction) on the plurality of bit line plugs BLP. According to embodiments, a first group of bit lines BL selected from among the plurality of bit lines BL may be connected to a first group of bit line plugs BLP connected to the plurality of first bit line pad stacks BPS1. A second group of bit lines BL selected from among the plurality of bit lines BL may be connected to a second group of bit line plugs BLP connected to the plurality of second bit line pad stacks BPS2. According to embodiments, each of the first group of bit lines BL may be connected to one bit line plug BLP of the first group of bit line plugs BLP per one first bit line pad stack BPS1. The first group of bit lines BL may extend across the plurality of first bit line pad stacks BPS1 in the first horizontal direction (the X direction). According to embodiments, each of the second group of bit lines BL may be connected to one bit line plug BLP of the second group of bit line plugs BLP per one second bit line pad stack BPS2. The second group of bit lines BL may extend across the plurality of second bit line pad stacks BPS2 in the first horizontal direction (the X direction). The first group of bit lines BL and the second group of bit lines BL may be spaced apart from each other in the second horizontal direction (the Y direction).

Referring to FIG. 5, the first multi-select line MSL1, the second multi-select line MSL2, and the plurality of bit lines BL extend parallel to each other in the first horizontal direction (the X direction) and may be disposed at a same vertical level. According to embodiments, the plurality of first common source lines CSL1, the plurality of second common source lines CSL2, the plurality of first block select lines BSL1, the plurality of second block select lines BSL2, and the plurality of horizontal word lines LWL extend parallel to each other in the second horizontal direction (the Y direction) and may be disposed at the same vertical level.

According to embodiments, the first multi-select line MSL1, the second multi-select line MSL2, the plurality of bit lines BL, the plurality of first common source lines CSL1, the plurality of second common source lines CSL2, the plurality of first block select lines BSL1, the plurality of second block select lines BSL2, and the plurality of horizontal word lines LWL may each be formed of metal, conductive metal nitride, a conductive semiconductor material, or a combination thereof.

Referring to FIG. 7B, FIG. 9A, FIG. 9B, FIG. 11A, FIG. 11B, and FIG. 12, each of the plurality of horizontal channel areas HC may include a first portion 127 extending in the first horizontal direction (the X direction) from a center portion of each of the plurality of horizontal channel areas HC, a second portion 128 in contact with the first bit line pad BP1 or the second bit line pad BP2, and a third portion 129 in contact with the first common source plug CSP1 or the second common source plug CSP2. According to embodiments, each of the plurality of horizontal channel areas HC may include a first boundary B1 between the first portion 127 and the second portion 128, and a second boundary B2 between the first portion 127 and the third portion 129.

According to embodiments, the first portion 127 of the plurality of first horizontal channel areas HC1 may be in contact with the plurality of gate plugs VGP, the first multi-select plug MSP1, and the second multi-select plug MSP2. According to embodiments, the second portion 128 of the plurality of first horizontal channel areas HC1 may be in contact with the plurality of first bit line pads BP1. According to embodiments, the third portion 129 of the plurality of first horizontal channel areas HC1 may be in contact with the plurality of first common source plugs CSP1.

According to embodiments, the first portion 127 of the plurality of second horizontal channel areas HC2 may be in contact with the plurality of gate plugs VGP, the first multi-select plug MSP1, and the second multi-select plug MSP2. According to embodiments, the second portions 128 of the plurality of second horizontal channel areas HC2 may be in contact with the plurality of second bit line pads BP2. According to embodiments, the third portion 129 of the plurality of second horizontal channel areas HC2 may be in contact with the plurality of second common source plugs CSP2.

According to embodiments, the first portion 127 of the plurality of horizontal channel areas HC may be formed of undoped polysilicon, doped polysilicon, a compound semiconductor material, an oxide semiconductor material, a two-dimensional semiconductor material, or a combination thereof. The compound semiconductor material may be selected from among a group IV-IV compound semiconductor, a group III-V compound semiconductor, a group II-VI compound semiconductor, or a group IV-VI compound semiconductor. The group IV-IV compound semiconductor may be selected from among SiGe, SiC, SiGeC, GeSn, SiSn, or SiGeSn. The group III-V compound semiconductor may be composed of a compound semiconductor including at least one of In, Ga, or Al as a group III element and at least one of As, P, or Sb as a group V element. According to embodiments, each of the second portion 128 and the third portion 129 of the plurality of horizontal channel areas HC may be formed of doped polysilicon.

In some embodiments, the first portion 127 may be formed of undoped polysilicon, and the second portion 128 and the third portion 129 may each be formed of doped polysilicon. In some embodiments, the first portion 127, the second portion 128, and the third portion 129 may each be formed of doped polysilicon, and in this case, the second portion 128 and the third portion 129 may have a higher doped concentration than the first portion 127. In some embodiments, the second portion 128 and the third portion 129 of the plurality of horizontal channel areas HC may be formed of polysilicon doped with a dopant having the same conductivity type as the plurality of first bit line pads BP1 and the plurality of second bit line pads BP2.

According to embodiments, the third portion 129 of the plurality of first horizontal channel areas HC1 may be in contact with at least some of the plurality of second block select plugs BSP2, and the third portion 129 of the plurality of second horizontal channel areas HC2 may be in contact with at least some of the plurality of first block select plugs BSP1.

In some embodiments, the plurality of first block select plugs BSP1 may include a plurality of first component plugs BSP1a and a plurality of second component plugs BSP1b separated from each other in the second horizontal direction (the Y direction) with the plurality of horizontal channel areas HC therebetween. In some embodiments, the plurality of first component plugs BSP1a and the plurality of second component plugs BSP1b may be alternately disposed along the second horizontal direction (the Y direction). In some embodiments, the plurality of first component plugs BSP1a may be disposed in a straight line along the second horizontal direction (the Y direction), and the plurality of second component plugs BSP1b may be separated from the plurality of first component plugs BSP1a in the first horizontal direction (the X direction) and disposed in a straight line along the second horizontal direction (the Y direction). In some embodiments, the plurality of first component plugs BSP1a may be closer to the plurality of second common source plugs CSP2 than to the plurality of second component plugs BSP1b in the first horizontal direction (the X direction).

In some embodiments, the third portion 129 of the plurality of second horizontal channel areas HC2 may be in contact with the plurality of first component plugs BSP1a and/or the plurality of second component plugs BSP1b. For example, the third portion 129 of the plurality of second horizontal channel areas HC2 may be in contact with the plurality of first component plugs BSP1a. For example, the third portion 129 of the plurality of second horizontal channel areas HC2 may be in contact with the plurality of first component plugs BSP1a and the plurality of second component plugs BSP1b. Accordingly, when a plurality of memory cell blocks are erased, a gate induced drain leakage (GIDL) phenomenon may be induced for the plurality of memory cell strings MS.

Referring to FIGS. 9A, FIG. 9B, FIG. 11A, FIG. 11B, and FIG. 12, in a planar view, among portions in which the plurality of first component plugs BSP1a may be in contact with the plurality of horizontal channel areas HC, a first imaginary line LCP1 passing relatively close to the plurality of second common source plugs CSP2 may be defined. In a planar view, among portions in which the plurality of second component plugs BSP1b may be in contact with the plurality of horizontal channel areas HC, a second imaginary line LCP2 passing relatively far from to the plurality of second common source plugs CSP2 may be defined. For example, the first imaginary line LCP1 and the second imaginary line LCP2 may be separated from each other in the first horizontal direction (the X direction) and elongated in the second horizontal direction (the Y direction). In some embodiments, the second boundary B2 of each of the plurality of second horizontal channel areas HC2 may be between the first imaginary line LCP1 and the second imaginary line LCP2 in a planar view. In FIG. 7B, projections of the plurality of first component plugs BSP1a and projections of the plurality of second component plugs BSP1b on a cross section taken along line B-B′ are indicated by dotted lines.

In some embodiments, the plurality of second block select plugs BSP2 may include a plurality of third component plugs BSP2a and a plurality of fourth component plugs BSP2b separated from each other in the second horizontal direction (the Y direction) with the plurality of horizontal channel areas HC therebetween. In some embodiments, the plurality of third component plugs BSP2a may be disposed in a straight line along the second horizontal direction (the Y direction), and the plurality of fourth component plugs BSP2b may be separated from the plurality of third component plugs BSP2a in the first horizontal direction (the X direction) and disposed in a straight line along the second horizontal direction (the Y direction). In some embodiments, the plurality of fourth component plugs BSP2b may be closer to the plurality of first common source plugs CSP1 than to the plurality of third component plugs BSP2a in the first horizontal direction (the X direction).

In some embodiments, the third portion 129 of the plurality of first horizontal channel areas HC1 may be in contact with the plurality of third component plugs BSP2a and/or the plurality of fourth component plugs BSP2b. For example, the third portion 129 of the plurality of first horizontal channel areas HC1 may be in contact with the plurality of third component plugs BSP2a. For example, the third portion 129 of the plurality of first horizontal channel areas HC1 may be in contact with the plurality of third component plugs BSP2a and the plurality of fourth component plugs BSP2b.

Referring to FIG. 9A, in a planar view, among portions in which the plurality of third component plugs BSP2a may be in contact with the plurality of horizontal channel areas HC, a third imaginary line LCP3 passing relatively close to the plurality of first common source plugs CSP1 may be defined. In a planar view, among portions in which the plurality of fourth component plugs BSP2b may be in contact with the plurality of horizontal channel areas HC, a fourth imaginary line LCP4 passing relatively far from the plurality of first common source plugs CSP1 may be defined. For example, the third imaginary line LCP3 and the fourth imaginary line LCP4 may be separated from each other in the first horizontal direction (the X direction) and elongated in the second horizontal direction (the Y direction). In some embodiments, the second boundary B2 of each of the plurality of first horizontal channel areas HC1 may be between the third imaginary line LCP3 and the fourth imaginary line LCP4 in a planar view.

Referring to FIG. 9B and FIG. 11B, a plurality of first imaginary circles ICA1 having a first radius R1 based on the center of each of the plurality of dummy plugs DP may be defined. In some embodiments, the first boundaries B1 of the plurality of horizontal channel areas HC may be arranged along boundaries of the plurality of first imaginary circles ICA1. For example, in a planar view, the first boundaries B1 of the plurality of horizontal channel areas HC may have curvatures.

In some embodiments, in a planar view, the first boundary B1 of each of the plurality of first horizontal channel areas HC1 may be between the first imaginary line LCP1 and the second imaginary line LCP2. In some embodiments, the second portion 128 of the plurality of first horizontal channel areas HC1 may be in contact with at least some of the plurality of first block select plugs BSP1. For example, the second portion 128 of the plurality of first horizontal channel areas HC1 may be in contact with the plurality of first component plugs BSP1a and/or the plurality of second component plugs BSP1b.

In some embodiments, in a planar view, the first boundary B1 of each of the plurality of second horizontal channel areas HC2 may be between the third imaginary line LCP3 and the fourth imaginary line LCP4. In some embodiments, the second portion 128 of the plurality of second horizontal channel areas HC2 may be in contact with at least some of the plurality of second block select plugs BSP2. For example, the second portion 128 of the plurality of second horizontal channel areas HC2 may be in contact with the plurality of third component plugs BSP2a and/or the plurality of fourth component plugs BSP2b.

Referring to FIG. 9B and FIG. 11B, a plurality of second imaginary circles ICA2 having a second radius R2 based on the center of each of the plurality of common source plugs CSP1 and CSP2 may be defined. In some embodiments, the second radius R2 of the second imaginary circle ICA2 may be smaller than the first radius R1 of the first imaginary circle ICA1. In some embodiments, the second boundaries B2 of the plurality of horizontal channel areas HC may be arranged along boundaries of the plurality of second imaginary circles ICA2. For example, in a planar view, the second boundaries B2 of the plurality of horizontal channel areas HC may have curvatures.

According to embodiments, in a planar view, the plurality of first horizontal channel areas HC1 and the plurality of second horizontal channel areas HC2 may be connected to bit line pads BP1 and BP2 and common source plugs CSP1 and CSP2 at opposite positions in the first horizontal direction (the X direction) and may be alternately disposed in the second horizontal direction (the Y direction). Accordingly, space efficiency may be increased, a degree of integration of the memory device 100 may be increased, and double cells MC1 and MC2 may simultaneously and independently operate. Also, the plurality of first and second common source plugs CSP1 and CSP2 may be formed together in a process of forming the plurality of gate plugs VGP, and a process cost may be reduced.

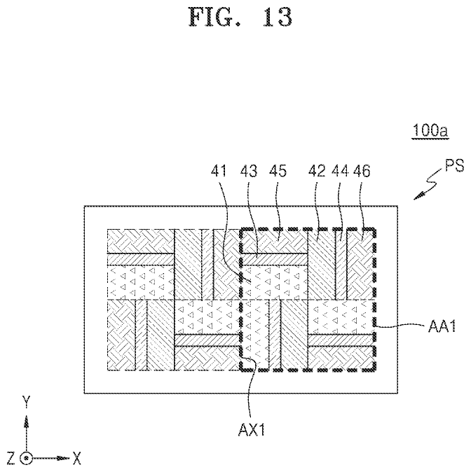

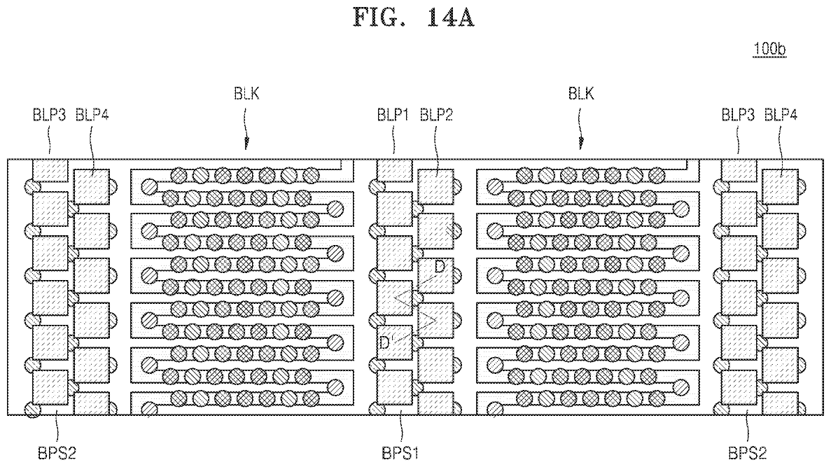

FIG. 13 is a plan view illustrating a main configuration of a peripheral circuit structure PS of a memory device 100a according to some embodiments. In FIG. 13, the peripheral circuit structure PS includes a plurality of first circuit areas AA1.

Referring to FIG. 13, the peripheral circuit structure PS of the memory device 100a may include the plurality of first circuit areas AA1. FIG. 13 illustrates that the peripheral circuit structure PS includes two first circuit areas AA1 and the two first circuit areas AA1 may be disposed in the first horizontal direction (the X direction). It should be understood that the inventive concept is not limited thereto. For example, the peripheral circuit structure PS may include three or more first circuit areas AA1. For example, the plurality of first circuit areas AA1 may be disposed in the second horizontal direction (the Y direction) or in the first horizontal direction (the X direction). Accordingly, from a relative point of view, operation reliability of the memory device 100a having a wider flat area may be increased.

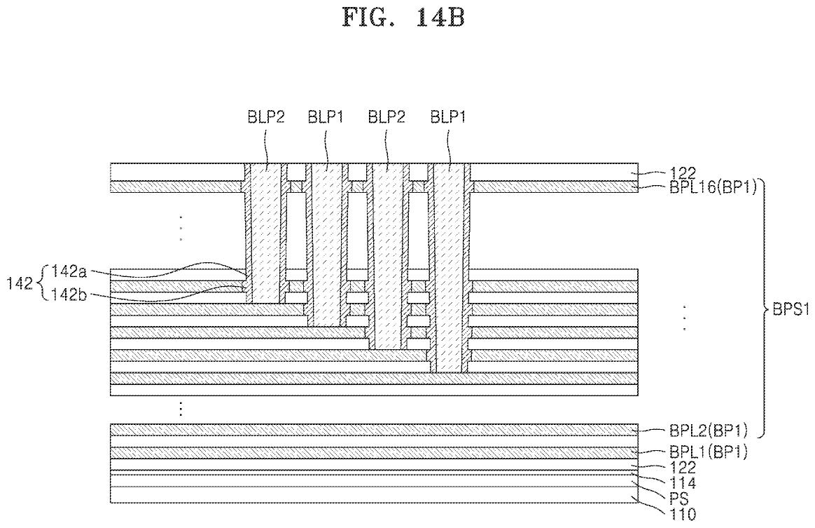

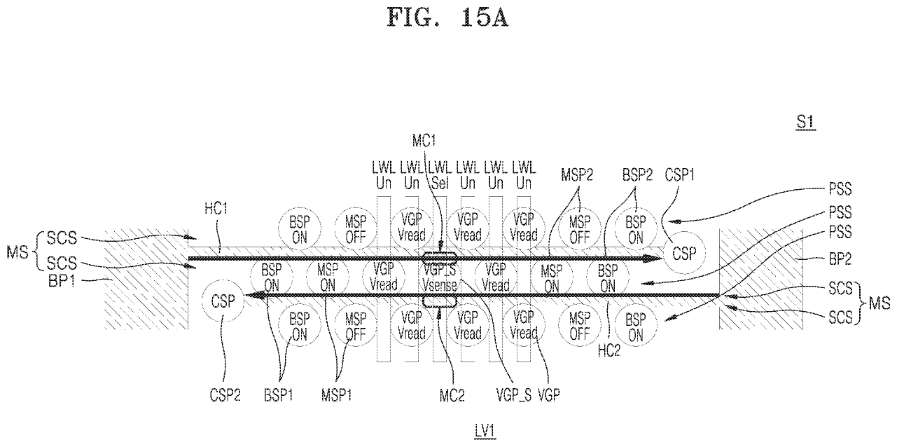

FIG. 14A is a plan view illustrating a cell array structure of a memory device 100b according to some other embodiments, and is an enlarged view of a part corresponding to FIG. 4. FIG. 14B is a cross-sectional view taken along line D-D′ of FIG. 14A.

Referring to FIG. 14A and FIG. 14B, a plurality of bit line plugs BLP may include a plurality of first component bit line plug BLP1, second component bit line plug BLP2, third component bit line plug BLP3, and fourth component bit line plug BLP4. According to embodiments, the plurality of first component bit line plugs BLP1 and the plurality of second component bit line plugs BLP2 may be respectively connected to the plurality of first bit line pad stacks BPS1, and the third component bit line plug BLP3 and the plurality of fourth component bit line plugs BLP4 may be respectively connected to the plurality of second bit line pad stacks BPS2.

According to embodiments, the plurality of first bit line pad stacks BPS1 may include a first group of first bit line pads BP1 and a second group of first bit line pads BP1 overlapping each other in the vertical direction (the Z direction). According to embodiments, the plurality of first component bit line plugs BLP1 may be respectively connected to the first group of first bit line pads BP1, and the plurality of second component bit line plugs BLP2 may be respectively connected to the second group of first bit line pads BP1.

According to embodiments, the plurality of first component bit line plugs BLP1 and the plurality of second component bit line plugs BLP2 may be configured to operate two adjacent memory cell blocks BLK. For example, the plurality of first component bit line plugs BLP1 may be involved in an operation the memory cell block BLK on one side of each of the plurality of first bit line pad stacks BPS1, and the second component bit line plugs BLP2 may be involved in an operation of the memory cell block BLK on the other side of the plurality of first bit line pad stacks BPS1.

Although FIG. 14B illustrates the plurality of first component bit line plugs BLP1 and the plurality of second component bit line plugs BLP2 connected to the plurality of first bit line pads BP1, it may be understood that the plurality of third component bit line plugs BLP3 and the plurality of fourth component bit line plugs BLP4 connected to the plurality of second bit lines pad BP2 have similar structures.

According to embodiments, a plurality of second bit line pad stacks (not illustrated) may include a first group of second bit line pads (not illustrated) and a second group of second bit line pads (not illustrated) overlapping each other in the vertical direction (the Z direction). According to embodiments, the plurality of third component bit line plugs BLP3 may be respectively connected to the first group of second bit line pads (not illustrated), and the plurality of fourth component bit line plugs BLP4 may be respectively connected to the second group of second bit line pads (not illustrated).

According to embodiments, the plurality of third component bit line plugs BLP3 and the plurality of fourth component bit line plugs BLP4 may be configured to operate two adjacent memory cell blocks BLK. For example, the plurality of third component bit line plugs BLP3 may be involved in an operation of the memory cell block BLK on one side of each of the plurality of second bit line pad stacks BPS2, and the plurality of fourth component bit line plugs BLP4 may be involved in an operation of the memory cell block BLK on the other side of each of the plurality of second bit line pad stacks BPS2.

According to embodiments, the plurality of first to fourth component bit line plugs BLP1, BLP2, BLP3, and BLP4 may be connected to different bit lines BL.

For example, each of a first group of bit lines BL selected from among the plurality of bit lines BL may be connected to one first component bit line plug BLP1 per one first bit line pad stack BPS1 and may extend across the plurality of first bit line pad stacks BPS1 in the first horizontal direction (the X direction). For example, each of a second group of bit lines BL selected from among the plurality of bit lines BL may be connected to one second component bit line plug BLP2 per one first bit line pad stack BPS1 and may extend across the plurality of first bit line pad stacks BPS1 in the first horizontal direction (the X direction). For example, each of a third group of bit lines BL selected from among the plurality of bit lines BL may be connected to one third component bit line plug BLP3 per one second bit line pad stack BPS2 and may extend across the plurality of second bit line pad stacks BPS2 in the first horizontal direction (the X direction). For example, each of a fourth group of bit lines BL selected from among the plurality of bit lines BL may be connected to one fourth component bit line plug BLP4 per one second bit line pad stack BPS2 and may extend across the plurality of second bit line pad stacks BPS2 in the first horizontal direction (the X direction).

According to embodiments, the plurality of first bit line pads BP1 overlapping each other in the vertical direction (the Z direction) may be connected to different bit lines BL, and the plurality of second bit line pads BP2 overlapping each other in the vertical direction (the Z direction) may be connected to different bit lines BL.

In some embodiments, the number of the plurality of first to fourth component bit line plugs BLP1, BLP2, BLP3, and BLP4 may be the same as each other.

FIG. 14B illustrates the plurality of first bit line pads BP1 overlapping each other in the vertical direction (the Z direction) and alternately in contact with the plurality of first component bit line plugs BLP1 and the plurality of second component bit line plugs BLP2 according to a stacking order. It should be understood that the inventive concept is not limited by FIG. 14B.

Further, FIG. 14B illustrates the memory device 100b according to embodiments including first to sixteenth bit line pad layers BPL1, . . . , BPL16, which may be in contact with eight first component bit line plugs BLP1 and eight second component bit line plugs BLP2. It should be understood that the inventive concept is not limited thereto. For example, the memory device 100b may include twenty bit line pad layers, and in this case, the number of plurality of first component bit line plugs BLP1 may be ten and the number of the plurality of second component bit line plugs BLP2 may be ten.

The memory device 100b according to embodiments may include a plurality of first to fourth component bit line plugs BLP1, BLP2, BLP3, and BLP4, and two memory cell blocks BLK adjacent to each other in the first horizontal direction (the X direction). The memory cell blocks BLK may simultaneously and independently operate. In this case, the memory cell strings MS operating simultaneously may be on different planes at different vertical levels.

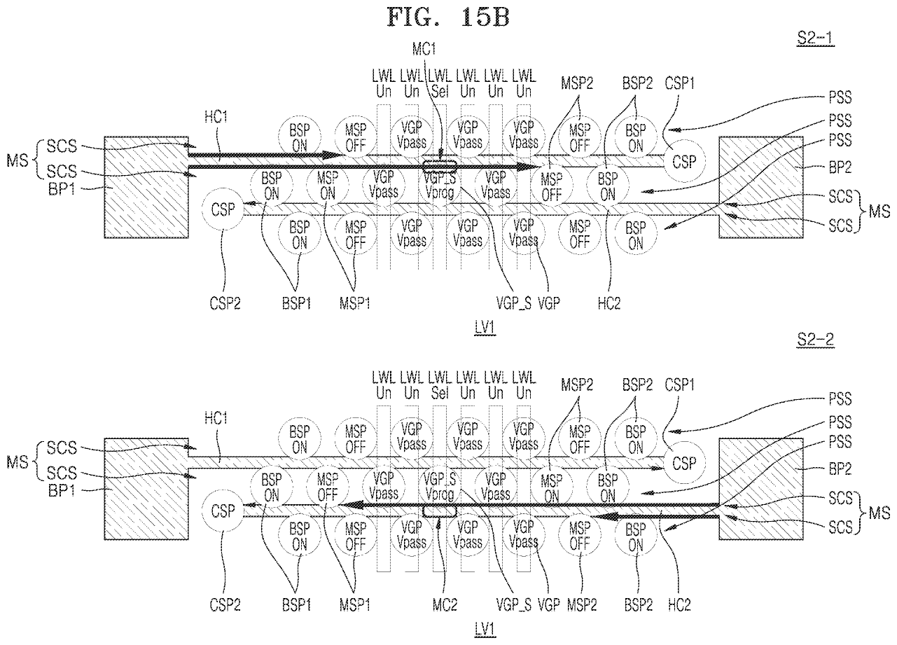

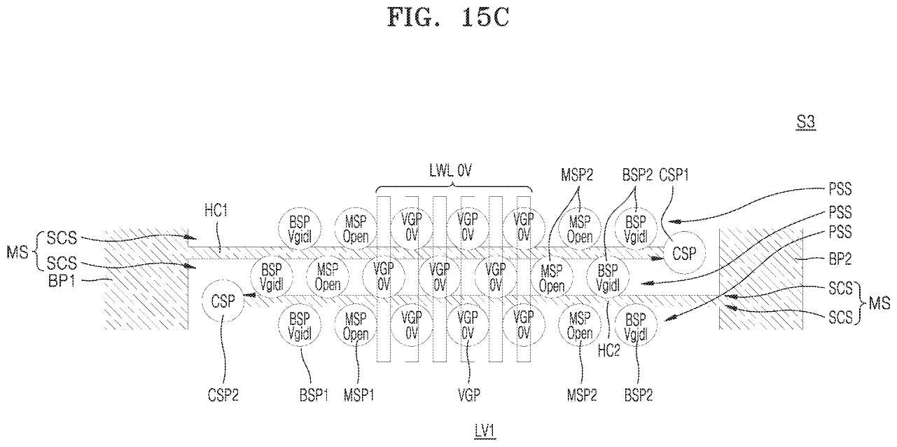

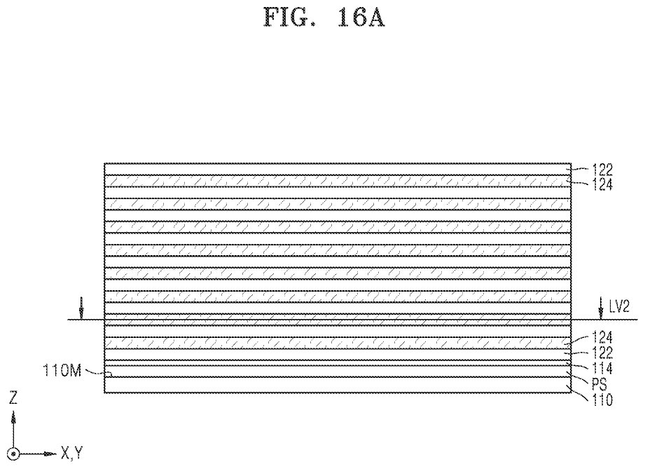

FIG. 15A, FIG. 15B, and FIG. 15C are plan views illustrating an operating method of the memory device 100, according to embodiments, and are enlarged views of corresponding portions of FIG. 9. Specifically, FIG. 15A is a view illustrating a read operation of the memory device 100, FIG. 15B is a view illustrating a program operation of the memory device 100, and FIG. 15C is a view illustrating an erase operation of the memory device 100.

Table 1 below shows voltages applied to respective components of the memory device 100 during a read operation of a double cell, a program operation of a first memory cell MC1 constituting the double cell, a program operation of the second memory cell MC2 constituting the double cell, and an erase operation of a memory cell block.

TABLE 1

| | | | LWL | | MSP | | |
|---|---|---|---|---|---|---|---|
| | BL, BL | LWL | Un- | MSP | Un- | | |
| | PAD | Select | select | Select | select | BSP | CSLP |
| Read | Vbl | Vsense | Vread | Vread | Voff | Vread | Vcsl |
| | | | | (ON) | (OFF) | (ON) | |
| Pro- | 0 V or | Vprog | Vpass | Vpass | Voff | Vpass | Vcc |
| gram 1 | Vcc | (ISPP) | | (ON) | (OFF) | (ON) | |
| Pro- | 0 V or | Vprog | Vpass | Vpass | Voff | Vpass | Vcc |
| gram 2 | Vcc | (ISPP) | | (ON) | (OFF) | (ON) | |
| Ease | Verase | 0 V | — | Float- | — | Vgidl | Float- |
| | | | | ing | | | ing |

Hereinafter, a read operation method S1 of the memory device 100 is described with reference to FIG. 15A and Table 1.

Vread may be applied to the plurality of first and second block select plugs BSP1 and BSP2 to select a first memory cell block in which a memory cell that is a target of a read operation is included among a plurality of memory cell blocks. Vsense may be applied to a first gate plug VGP_S selected from among the plurality of gate plugs VGP, and Vread may be applied to the other gate plugs VGP. For example, the first gate plug VGP_S may be included in a first plug string PSS selected from among the plurality of plug strings PSS.

The memory cell that is a target of a read operation may be at the first vertical level LV1. For example, a read operation may be performed on a first double cell at the first vertical level among a plurality of double cells to which a voltage is applied by the first gate plug VGP_S. The first double cell may include the first memory cell MC1 and the second memory cell MC2.

When the read operation is performed on the first memory cell MC1 of the first double cell, Vbl may be applied to the first bit line pad BP1 at the first vertical level LV1. Vread may be applied to the first multi-select plug MSP1 of the first plug string PSS. At the same time, Voff may be applied to the first multi-select plug MSP1 of the second plug string PSS selected from among the plurality of plug strings PSS and separated the first plug string PSS with the first horizontal channel area HC1 therebetween. Accordingly, one sub-cell string SCS may be selected, and in this case, the first multi-select plug MSP1 may perform a string selection function. Vread may be applied to the second multi-select plug MSP2 of the first plug string PSS, and Voff may be applied to the second multi-select plug MSP2 of the second plug string PSS. In this case, the second multi-select plug MSP2 may perform a ground selection function. Vesl may be applied to the first common source plug CSP1 of the first memory cell block.

When the read operation is performed on the second memory cell MC2 of the first double cell, Vbl may be applied to the second bit line pad BP2 at the first vertical level LV1. Vread may be applied to the second multi-select plug MSP2 of the first plug string PSS. At the same time, Voff may be applied to the second multi-select plug MSP2 of the third plug string PSS selected from among the plurality of plug strings PSS and separated the first plug string PSS with the second horizontal channel area HC2 therebetween. Accordingly, one sub-cell string SCS may be selected, and in this case, the second multi-select plug MSP2 may perform a string selection function. Vread may be applied to the first multi-select plug MSP1 of the first plug string PSS, and Voff may be applied to the first multi-select plug MSP1 of the third plug string PSS. In this case, the first multi-select plug MSP1 may perform a ground selection function. Vesl may be applied to the second common source plug CSP2 of the first memory cell block.

The read operations of the first memory cell MC1 and the second memory cell MC2 of the memory device 100 according to embodiments may be simultaneously and independently performed as described herein.

Hereinafter, program operation methods S2_1 and S2_2 of the memory device 100 may be described with reference to FIG. 15B and Table 1. In FIG. 15B, the same reference numerals as in FIG. 15A denote the same members, and redundant descriptions thereof may be omitted here.

Vpass may be applied to the plurality of first and second block select plugs BSP1 and BSP2 to select a first memory cell block in which a memory cell that is a target of a program operation is included among a plurality of memory cell blocks. Vprog may be applied to the first gate plug VGP_S selected from among the plurality of gate plugs VGP, and Vpass may be applied to the other gate plugs VGP. For example, the first gate plug VGP_S may be included in a first plug string PSS selected from among the plurality of plug strings PSS.

A memory cell that is a target of a program operation may be at the first vertical level LV1. For example, the program operation may be performed on a first double cell at a first vertical level among a plurality of double cells to which a voltage is applied by the first gate plug VGP_S. The first double cell may include the first memory cell MC1 and the second memory cell MC2.

When the program operation is performed on the first memory cell MC1 (S2_1), 0 V may be applied to the first bit line pad BP1 at the first vertical level LV1. Vpass may be applied to the first multi-select plug MSP1 of the first plug string PSS, and Voff may be applied to the first multi-select plug MSP1 of the second plug string PSS. At the same time, Voff may be applied to the second multi-select plug MSP2 of the first plug string PSS and the second multi-select plug MSP2 of the second plug string PSS. Vcc may be applied to the first common source plug CSP1 of the first memory cell block. In this case, Vcc may be applied to the second bit line pad BP2 at the first vertical level LV1, Voff may be applied to the first multi-select plug MSP1 and the second multi-select plug MSP2 of the third plug string PSS, and Vcc may be applied to the second common source plug CSP2.

When the program operation is performed on the second memory cell MC2 (S2_2), 0 V may be applied to the second bit line pad BP2 at the first vertical level LV1. Vpass may be applied to the second multi-select plug MSP2 of the first plug string PSS, and Voff may be applied to the second multi-select plug MSP2 of the third plug string PSS. At the same time, Voff may be applied to the first multi-select plug MSP1 of the first plug string PSS and the first multi-select plug MSP1 of the third plug string PSS. Vcc may be applied to the second common source plug CSP2 of the first memory cell block. In this case, Vcc may be applied to the first bit line pad BP1 at the first vertical level LV1, Voff may be applied to the first multi-select plug MSP1 and the second multi-select plug MSP2 of the second plug string PSS, and Vcc may be applied to the first common source plug CSP1.

Hereinafter, an erase operation method S3 of the memory device 100 is described with reference to FIG. 15C and Table 1. In FIG. 15C, the same reference numerals as in FIG. 15A denote the same members, and redundant descriptions thereof may be omitted here.

A first memory cell block that is an object of an erase operation may be selected from among a plurality of memory cell blocks. According to embodiments, Vgidl may be applied to the plurality of first block select plugs BSP1 and the plurality of second block select plugs BSP2 of the first memory cell block, and Verase may be applied to the plurality of first bit line pads BP1 and the plurality of second bit line pads BP2 overlapping each other in the vertical direction (the Z direction). For example, Vgidl has an absolute value less than Verase and may be a voltage for controlling the GIDL current. At the same time, 0 V may be applied to the plurality of horizontal word lines LWL on the first memory cell block, and the plurality of first multi-select plugs MSP1, the plurality of second multi-select plugs MSP2, the plurality of first common source plugs CSP1, and the plurality of second common source plugs CSP2 may be floated.

For example, the erase operation may be independently performed on each memory cell block.

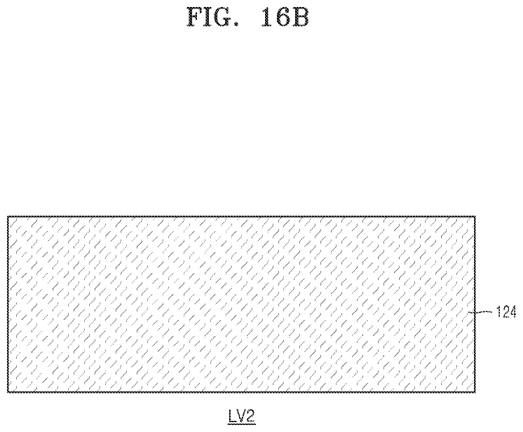

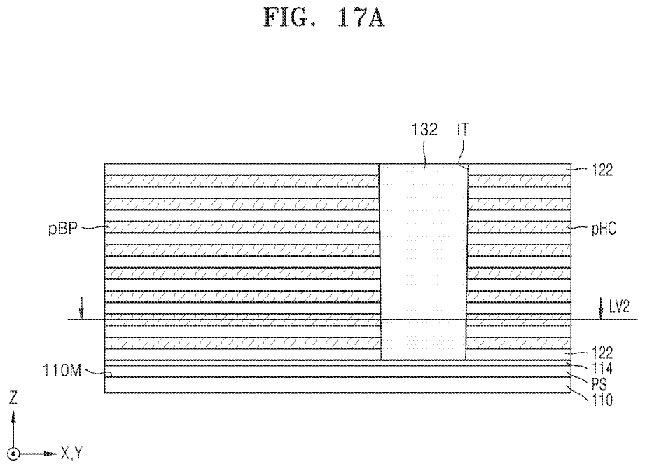

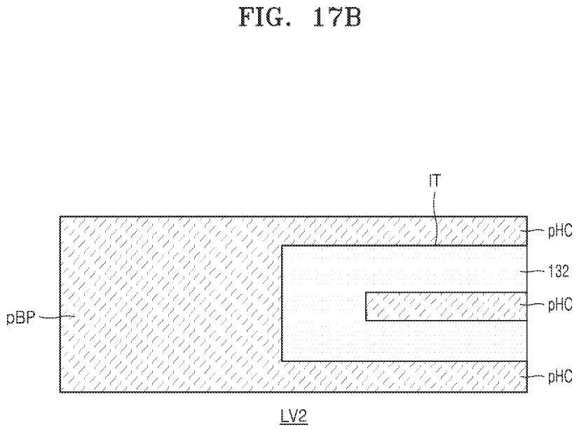

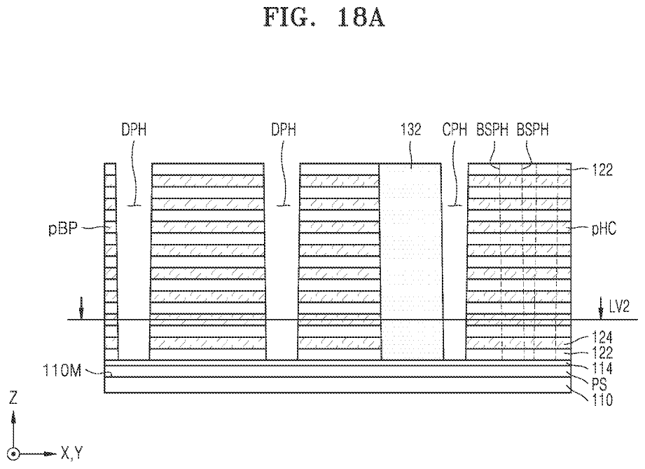

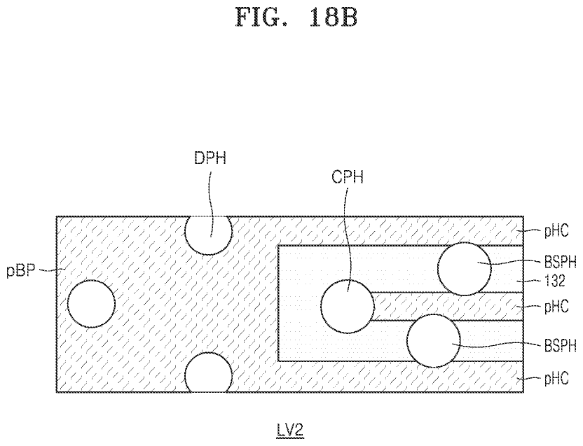

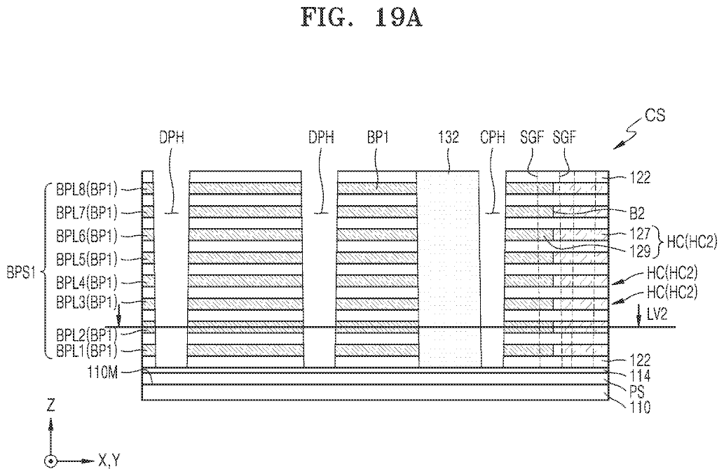

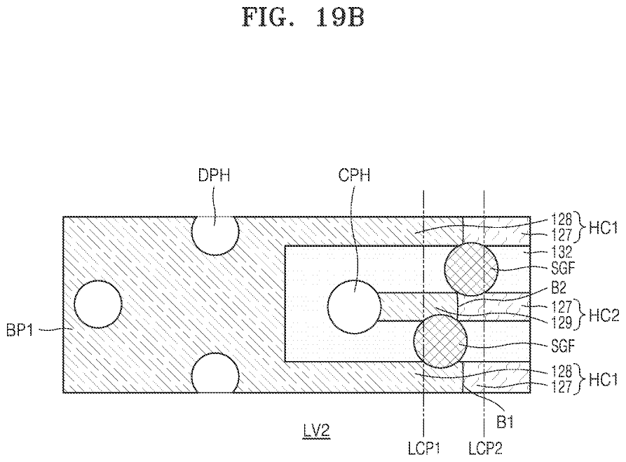

FIG. 16A, FIG. 17A, FIG. 18A, and FIG. 19A are cross-sectional views illustrating process sequence a method of manufacturing a memory device, according to embodiments, and FIG. 16B, FIG. 17B, FIG. 18B, and FIG. 19B are plan views respectively illustrating configurations of FIG. 16A, FIG. 17A, FIG. 18A, and FIG. 19A at a second vertical level. Specifically, FIG. 16A, FIG. 17A, FIG. 18A, and FIG. 19A are cross-sectional views illustrating corresponding portions in FIG. 7B, and FIG. 16B, FIG. 17B, FIG. 18B, and FIG. 19B are plan views illustrating corresponding portions in FIG. 12.

A method of manufacturing the memory device 100 illustrated in FIGS. 3A to 12 is described with reference to FIGS. 16A to 19B as an example. In FIGS. 16A to 19B, the same reference numerals as in FIGS. 3A to 12 denote the same members, and redundant descriptions thereof may be omitted here.

Referring to FIG. 16A and FIG. 16B, the peripheral circuit structure PS and the etch stop layer 114 may be sequentially formed over the substrate 110. A stacking structure, in which the plurality of interlayer insulating layers 122 and the plurality of semiconductor layers 124 may be alternately stacked one by one, may be formed on the etch stop layer 114.

In some embodiments, the plurality of interlayer insulating layers 122 may be formed of silicon oxide, and the plurality of semiconductor layers 124 may be formed of a group IV compound semiconductor material. For example, the group IV compound semiconductor may be Si.

Referring to FIG. 17A and FIG. 17B, a partial area of the result of FIG. 16A and FIG. 16B may be etched to form an insulating pattern trench IT. For example, the etch stop layer 114 may be exposed by the insulating pattern trench IT. An insulating pattern structure 132 may be disposed in the insulating pattern trench IT. For example, the insulating pattern structure 132 may fill the insulating pattern trench IT. Accordingly, a plurality of preliminary bit line pads pBP overlapping each other in the vertical direction (the Z direction) and a plurality of preliminary horizontal channel areas pCH overlapping each other in the vertical direction (the Z direction) may be formed.

Referring to FIG. 18A and FIG. 18B, partial areas of the result of FIG. 17A and FIG. 17B may be etched to form a plurality of dummy plug holes DPH, a plurality of common source plug holes CPH, a plurality of block select plug holes BSPH, a plurality of multi-select plug holes (not illustrated), and a plurality of gate plug holes (not illustrated). The plurality of dummy plug holes DPH, the plurality of common source plug holes CPH, the plurality of block select plug holes BSPH, the plurality of multi-select plug holes (not illustrated), and the plurality of gate plug holes (not illustrated) may be separated from each other in the horizontal direction (the X direction and/or the Y direction) and may expose the etch stop layer 114. The plurality of common source plug holes CPH may be formed in the same process as the plurality of dummy plug holes DPH, the plurality of block select plug holes BSPH, the plurality of multi-select plug holes (not illustrated), and the plurality of gate plug holes (not illustrated), and a process cost may be reduced.

Referring to FIG. 19A and FIG. 19B, a plurality of sacrificial insulation plugs SGF may be formed in the plurality of block select plug holes (BSPH), the plurality of multi-select plug holes (not illustrated), and the plurality of gate plug holes (not illustrated) of FIG. 18A and FIG. 18B. For example, the sacrificial insulation plugs SGF may each be composed of a silicon nitride film.

A plurality of common source plug sacrificial layers (not illustrated), formed of silicon nitride, may be formed in the plurality of common source plug holes CPH. In some other embodiments, the sacrificial insulation plug SGF may also be formed in the plurality of common source plug holes CPH, the plurality of block select plug holes BSPH, the plurality of multi-select plug holes (not illustrated), and the plurality of gate plug holes (not illustrated).

A first ion implantation process, in which dopants are implanted into the plurality of preliminary bit line pads pBP, may be performed by implanting gas phase dopants into the plurality of dummy plug holes DPH. For example, dopants may be implanted into the plurality of preliminary bit line pads pBP through lateral diffusion from side surfaces of the plurality of preliminary bit line pads pBP exposed through the plurality of dummy plug holes DPH. For example, the dopants may be implanted into the plurality of dummy plug holes DPH and may be isotropically diffused through an annealing process. In this case, the plurality of common source plug holes CPH may be blocked by a plurality of common source plug sacrificial films (not illustrated), and accordingly, impurities may not be introduced.

The plurality of common source plug sacrificial films (not illustrated) may be removed to expose the plurality of common source plug holes CPH, and a second ion implantation process, in which dopants are implanted into the plurality of preliminary bit line pads pBP and partial areas of the plurality of preliminary horizontal channel areas pHC, may be performed by implanting vapor phase dopants into the plurality of dummy plug holes DPH and the plurality of common source plug holes CPH. For example, the gas phase dopants may be implanted into the plurality of dummy plug holes DPH and the plurality of common source plug holes CPH and may be isotropically diffused through an annealing process.

In some embodiments, as the second ion implantation process is performed, an area, into which dopants are implanted through the plurality of dummy plug holes DPH among the plurality of preliminary bit line pads pBP, may be wider than the result of the first ion implantation process. For example, during the second ion implantation process, the dopants implanted through the plurality of dummy plug holes DPH may be diffused to entire of the plurality of preliminary bit line pads pBP and a portion of the preliminary horizontal channel area pHC in contact with the plurality of preliminary bit line pads pBP. For example, in a planar view, the plurality of bit line pad layers BPL1, BPL2, . . . , BPL8 overlapping each other in the vertical direction (Z direction) and the second portion 128 of the plurality of horizontal channel areas HC may be formed by diffusing dopants to a boundary of the imaginary circle ICA described with reference to FIG. 9 and FIG. 11. In this case, the first boundary B1 may be formed between the first portion 127 in which dopants are not implanted and the second portion 128 in which dopants are implanted.

In some embodiments, vapor phase dopants may be implanted into the plurality of common source plug holes CPG during the second ion implantation process and may be laterally diffused into the plurality of preliminary horizontal channel areas pHC through annealing. For example, in a planar view, the third portion 129 of the plurality of horizontal channel areas HC overlapping each other in the vertical direction (the Z direction) may be formed by diffusing the vapor phase dopants to the boundary of the imaginary circle ICA described with reference to FIG. 9 and FIG. 11. In this case, the second boundary B2 may be formed between the first portion 127 in which dopants are not implanted and the third portion 129 in which dopants are implanted.

In some embodiments, the diffusion of dopants through the plurality of common source plug holes CPG and the diffusion of dopants through the plurality of dummy plug holes DPH may not affect each other by the insulating pattern structure 132 and may be adjusted independently of each other. In some embodiments, the diffusion of dopants through the plurality of common source plug holes CPG and the diffusion of dopants through the plurality of dummy plug holes DPH may be simultaneously performed. In some other embodiments, the diffusion of dopants through the plurality of common source plug holes CPG and the diffusion of dopants through the plurality of dummy plug holes DPH may be performed at different process.

For example, according to isotropic implantation of impurities, the first boundary B1 between the first portion 127 and the second portion 128 may have a curvature, and the second boundary B2 between the first portion 127 and the third portion 129 may have a curvature. The curvatures may correspond to a portion of a boundary formed by overlapping ones of the plurality of imaginary circles ICA in a plan view. For example, in the second ion implantation process, the second boundary B2 may be formed between the first imaginary line LCP1 and the second imaginary line LCP2 and may be formed between the third imaginary line LCP3 and the fourth imaginary line LCP4 as illustrated in FIG. 9. In some embodiments, in the second ion implantation process, the first boundary B1 may be formed between the first imaginary line LCP1 and the second imaginary line LCP2 or between the third imaginary line LCP3 and the fourth imaginary line LCP4.

The plurality of dummy plugs DP may be respectively formed in the plurality of dummy plug holes DPH, and a plurality of first and second common source plugs may be respectively formed in the plurality of common source plug holes CPH. The plurality of sacrificial insulation plugs SGF may be removed, and a plurality of first and second block select plugs maybe formed in the plurality of block select plug holes BSPH, a plurality of first and second multi-select plugs may be formed in a plurality of multi-select plug holes (not shown), and a plurality of gate plugs may be formed in a plurality of gate plug holes (not shown). The memory device 100 may be manufactured by forming a plurality of contacts and first and second horizontal wires over a plurality of first and second bit line pads, a plurality of first and second common source plugs, a plurality of first and second block select plugs, a plurality of first and second multi-select plugs, and a plurality of first and second gate plugs.

While the inventive concept has been particularly shown and described with reference to embodiments thereof, it will be understood that various changes in form and details may be made therein without departing from the spirit and scope of the following claims.

What is claimed is:

1. A memory device comprising:
a first bit line pad and a second bit line pad on a substrate and separated from each other in a first horizontal direction;
a plurality of horizontal channel areas extending parallel in the first horizontal direction between the first bit line pad and the second bit line pad, and alternately connected to the first bit line pad and the second bit line pad at first end portions of the plurality of horizontal channel areas;
a plurality of common source plugs connected to second end portions of the plurality of horizontal channel areas opposite to the first end portions; and
a plurality of gate plugs extending in a vertical direction and disposed between the plurality of horizontal channel areas, and respectively having end portions in a second horizontal direction perpendicular to the first horizontal direction in contact with the plurality of horizontal channel areas.

2. The memory device of claim 1, further comprising:
a plurality of horizontal word lines extending parallel to each other in the second horizontal direction on the plurality of gate plugs and connected to the plurality of gate plugs,
wherein a first horizontal word line of the plurality of horizontal word lines is connected to a first gate plug of the plurality of gate plugs,
a first end portion of the end portions of the first gate plug is in contact with a first horizontal channel area of the plurality of horizontal channel areas,
a second horizontal word line of the plurality of horizontal word lines adjacent to the first horizontal word line is connected to a second gate plug of the plurality of gate plugs, and
the second gate plug is separated from the first gate plug by the first horizontal channel area.

3. The memory device of claim 1, wherein the plurality of gate plugs are arranged in a zigzag pattern along the second horizontal direction.

4. The memory device of claim 1, further comprising:
a plurality of first multi-select plugs and a plurality of second multi-select plugs, separated from each other in the first horizontal direction with the plurality of gate plugs therebetween,
wherein the plurality of first multi-select plugs are arranged, one by one, between the plurality of horizontal channel areas, and end portions of each of the plurality of first multi-select plugs in the second horizontal direction are in contact with the plurality of horizontal channel areas, and
the plurality of second multi-select plugs are arranged, one by one, between the plurality of horizontal channel areas, and end portions of each of the plurality of second multi-select plugs in the second horizontal direction are in contact with the plurality of horizontal channel areas.

5. The memory device of claim 4, further comprising:
a plurality of first block select plugs and a plurality of second block select plugs separated from each other in the first horizontal direction with the plurality of first multi-select plugs and the plurality of second multi-select plugs therebetween,
wherein the plurality of first block select plugs are arranged, one by one, between the plurality of horizontal channel areas, and end portions of each of the plurality of first block select plugs in the second horizontal direction are in contact with the plurality of horizontal channel areas, and
the plurality of second block select plugs are arranged one by one between the plurality of horizontal channel areas, and end portions of each of the plurality of second block select plugs in the second horizontal direction are in contact with the plurality of horizontal channel areas.

6. The memory device of claim 1, wherein each of the plurality of horizontal channel areas comprises:
a first portion in contact with corresponding ones of the plurality of gate plugs adjacent to the first portion;
a second portion in contact with one of the first bit line pad or the second bit line pad; and
a third portion in contact with a corresponding one of the plurality of common source plugs, and
the first portions include an undoped polysilicon, and both of the second portion and the third portion include a polysilicon doped with impurities.

7. The memory device of claim 6, further comprising:
a plurality of dummy plugs passing through the first bit line pad and the second bit line pad in the vertical direction,
wherein a first boundary between the first portion and the second portion is arranged along a boundary of a first radius, based on a center of each of the plurality of dummy plugs, and
a second boundary between the first portion and the third portion is arranged along a boundary of a second radius, based on a center of each of the plurality of common source plugs.

8. The memory device of claim 6, further comprising:
a plurality of first multi-select plugs and a plurality of second multi-select plugs separated from each other in the first horizontal direction with the plurality of gate plugs therebetween; and
a plurality of first block select plugs and a plurality of second block select plugs separated from each other in the first horizontal direction with the plurality of first multi-select plugs and the plurality of second multi-select plugs therebetween,
wherein the third portion of each of the plurality of horizontal channel areas is in contact with at least one of the plurality of first block select plugs or at least one of the plurality of second block select plugs.

9. The memory device of claim 1, wherein the plurality of common source plugs comprise:
a plurality of first common source plugs electrically connected to the first bit line pad; and
a plurality of second common source plugs electrically connected to the second bit line pad,
the plurality of first common source plugs are connected to a first common source line extending in the second horizontal direction over the plurality of first common source plugs, and
the plurality of second common source plugs are connected to a second common source line extending in the second horizontal direction over the plurality of second common source plugs.

10. The memory device of claim 1, further comprising:
a first bit line plug connected to the first bit line pad;
a second bit line plug connected to the second bit line pad;
a first bit line connected to the first bit line plug and extending in the first horizontal direction over the first bit line plug; and
a second bit line connected to the second bit line plug, separated from the first bit line in the second horizontal direction over the second bit line plug, and extending in the first horizontal direction.

11. A memory device comprising:
a cell array structure including a plurality of memory cells arranged on a substrate in a first horizontal direction and a second horizontal direction, which are parallel to a surface of the substrate and are orthogonal to each other, and in a vertical direction perpendicular to the surface,
wherein the cell array structure includes:
a plurality of first horizontal channel areas comprising a first group extending parallel to each other in the first horizontal direction and a second group overlapping each other at a plurality of vertical levels and separated from each other in the vertical direction on the substrate;
a plurality of second horizontal channel areas separated from the plurality of first horizontal channel areas in the second horizontal direction, and comprising a third group extending parallel to each other in the first horizontal direction, and a fourth group overlapping each other at the plurality of vertical levels and separated from each other in the vertical direction on the substrate;
a plurality of gate plugs extending in the vertical direction between the first group of the plurality of first horizontal channel areas and the third group of the plurality of second horizontal channel areas, each having first end portions in contact with the plurality of first horizontal channel areas, and each having second end portions in contact with the plurality of second horizontal channel areas; and
a plurality of bit line pad layers each including a first bit line pad and a second bit line pad separated from each other in the first horizontal direction with the plurality of first horizontal channel areas and the plurality of second horizontal channel areas therebetween and the plurality of bit line pad layers overlap each other at the plurality of vertical levels and separated from each other in the vertical direction,
wherein a first bit line pad layer of the plurality of bit line pad layers is disposed at a first vertical level of the plurality of vertical levels,
the first bit line pad of the first bit line pad layer in contact with first end portions of the first group of the plurality of first horizontal channel areas at the first vertical level, and
the second bit line pad of the first bit line pad layer in contact with first end portions of the third group of the plurality of second horizontal channel areas at the first vertical level.

12. The memory device of claim 11, wherein the first group of the plurality of first horizontal channel areas and the third group of the plurality of second horizontal channel areas are alternately arranged along the second horizontal direction.

13. The memory device of claim 11, further comprising:
a plurality of bit line plugs respectively connected to the plurality of bit line pad layers at different levels in the vertical direction,
wherein a first bit line plug of the plurality of bit line plugs and connected to the first bit line pad layer vertically penetrates a second bit line pad layer of the plurality of bit line pad layers and arranged at a vertical level higher than the first bit line pad layer.

14. The memory device of claim 13, further comprising:
a plurality of interlayer insulating layers respectively arranged between the plurality of bit line pad layers in the vertical direction; and
a plurality of plug insulating layers respectively covering sidewalls of the plurality of bit line plugs,
wherein a first plug insulating layer, which covers a sidewall of the first bit line plug among the plurality of plug insulating layers, comprises:
a first portion in contact with a first interlayer insulating layer between the first bit line pad layer and the second bit line pad layer; and
a second portion in contact with the second bit line pad layer, wherein
the second portion protrudes from the sidewall of the first bit line plug more than the first portion.

15. The memory device of claim 11, further comprising:
a plurality of first multi-select plugs and a plurality of second multi-select plugs, extending in the vertical direction, and separated from each other in the first horizontal direction with the plurality of gate plugs therebetween; and
a plurality of first block select plugs and a plurality of second block select plugs, extending in the vertical direction, and separated from each other in the first horizontal direction with the plurality of first multi-select plugs and the plurality of second multi-select plugs therebetween.

16. The memory device of claim 15, further comprising:
a plurality of block select lines extending parallel to each other in the second horizontal direction and connected to the plurality of first block select plugs and the plurality of second block select plugs;
a plurality of multi-select lines extending parallel to each other in the first horizontal direction and connected to the plurality of first multi-select plugs and the plurality of second multi-select plugs; and
a plurality of horizontal word lines extending parallel to each other in the second horizontal direction and connected to the plurality of gate plugs.

17. The memory device of claim 15, further comprising:
a peripheral circuit structure interposed between the substrate and the cell array structure and, in a planar view, including a first circuit area including a word line decoder area, a block select decoder area, a page buffer area, and a multi-select decoder area,
wherein the first circuit area has a first central axis in the first horizontal direction and a second central axis in the second horizontal direction in the planar view defining a quadrant, and the first circuit area includes a first area, a second area, a third area, and a fourth area arranged in a counterclockwise direction around the quadrant, wherein
the word line decoder area is in contact with the second central axis and a portion of the first central axis, in the first area and the third area,
the block select decoder area is in contact with the word line decoder area and a portion of the first central axis, in the first area and the third area,
the page buffer area is in contact with the first central axis and a portion of the second central axis, in the second area and the fourth area, and
the multi-select decoder area is in contact with the page buffer area and a portion of the second central axis, in the second area and the fourth area.

18. The memory device of claim 17, wherein the peripheral circuit structure includes a plurality of first circuit areas, and
the plurality of first circuit areas are in contact with each other and are arranged in the first horizontal direction.

19. A memory device comprising:
a plurality of first bit line pad stacks and a plurality of second bit line pad stacks alternately separated from each other in a first horizontal direction; and
a plurality of memory cell blocks respectively arranged between the plurality of first bit line pad stacks and the plurality of second bit line pad stacks in the first horizontal direction,
wherein each of the plurality of memory cell blocks comprises:
a plurality of first horizontal channel areas extending in the first horizontal direction, and repeatedly arranged in a second horizontal direction perpendicular to the first horizontal direction and in a vertical direction, on a substrate;
a plurality of second horizontal channel areas separated from the plurality of first horizontal channel areas in the second horizontal direction, extending in the first horizontal direction, and repeatedly arranged in the second horizontal direction and the vertical direction, on the substrate; and
a plurality of gate plugs extending in the vertical direction, each having first end portions in contact with some of the plurality of first horizontal channel areas and second end portions opposite to the first end portions in the second horizontal direction in contact with some of the plurality of second horizontal channel areas, wherein
the plurality of first bit line pad stacks include a plurality of first bit line pads, wherein the plurality of first bit line pads extend in the second horizontal direction and are in contact with the plurality of first horizontal channel areas, and overlap each other at positions separated from each other in the vertical direction,
the plurality of second bit line pad stacks include a plurality of second bit line pads, wherein the plurality of second bit line pads extend in the second horizontal direction and are in contact with the plurality of second horizontal channel areas, and overlap each other at positions separated from each other in the vertical direction, and
the plurality of first horizontal channel areas and the plurality of second horizontal channel areas are alternately arranged along the second horizontal direction.

20. The memory device of claim 19, wherein the plurality of gate plugs are arranged in a zigzag pattern along the second horizontal direction.
